(19) United States
(12) Patent Application Publication
(10) Pub. No.: US 2012/0133383 A1
(43) Pub. Date: May 31, 2012

(54) PROBE, PROBE CARD AND ELECTRONIC DEVICE TESTING APPARATUS

(75) Inventor: Tetsuya Kuitani, Saitama (JP)

(73) Assignee: ADVANTEST CORPORATION, Tokyo (JP)

(21) Appl. No.: 13/388,152

(22) PCT Filed: Aug. 31, 2009
(86) PCT No.: PCT/JP2009/065173

§ 371 Date: Jan. 31, 2012

(51) Int. Cl. G01R 31/20

(52) U.S. Cl. 324/754.07

(57) ABSTRACT

A probe includes: a single base portion; a plurality of beam portions whose rear end sides are supported by the base portion and whose front end sides protrude from the base portion; and a plurality of conductive patterns formed on surfaces of the beam portions. At least a part of the plurality of beam portions has a beam bent portion which is bent in a direction inclined to or substantially perpendicular to a protruding direction of the beam portions.

### TECHNICAL FIELD

The present invention relates to a probe to be used for testing electronic devices (hereinafter also referred simply to as DUTs (Devices Under Test)), such as semiconductor integrated circuit elements, formed on a semiconductor wafer and also relates to a probe card and an electronic device testing apparatus which comprise the probe.

### BACKGROUND ART

For testing DUTs on a semiconductor wafer, a probe card having a board on which a number of probes are mounted is used. Front ends of the probes are pressed onto input and output terminals of DUTs so as to electrically contact them, thereby performing the test of those DUTs (refer to Patent Document 1, for example).

### PRIOR ART DOCUMENTS

### Patent Document(s)

[Patent Document 1] Japanese Patent Application Publication No. 2000-249722

### SUMMARY OF THE INVENTION

### Problems to be Solved by the Invention

According to the above-described probes, the front ends thereof are linearly aligned, and therefore it is impossible to deal with the test for DUTs in which input and output terminals are two-dimensionally arranged, such as disposed in plural columns.

Problems to be solved by the invention include providing a probe capable of dealing with the test for electronic devices each whose has input and output terminals arranged in two-dimensional fashion.

### Means for solving the Problems

(1) The probe according to the present invention is a probe which contacts terminals of an electronic device under test, the probe characterized by comprising: a single base portion; a plurality of beam portions whose rear end sides are supported by the base portion and whose front end sides protrude from the base portion; and a plurality of conductive patterns formed on surfaces of the beam portions, wherein at least a part of the plurality of beam portions has a beam bent portion which is bent in a direction inclined to or substantially perpendicular to a protruding direction of the beam portions.

(2) The probe according to the present invention is a probe which contacts terminals of an electronic device under test, the probe characterized by comprising: a single base portion; a plurality of beam portions whose rear end sides are supported by the base portion and whose front end sides protrude from the base portion; and a plurality of conductive patterns formed on surfaces of the beam portions, wherein the plurality of beam portions include: a first beam portion protruding from the base portion; and a second beam portion protruding from the base portion and having a beam bent portion which is bent in a direction inclined to or substantially perpendicular to a protruding direction of the first beam portion.

(3) The probe according to the present invention is a probe which contacts terminals of an electronic device under test, the probe characterized by comprising: a single base portion; a plurality of beam portions whose rear end sides are supported by the base portion and whose front end sides protrude from the base portion; and a plurality of conductive patterns formed on surfaces of the beam portions, wherein the plurality of beam portions include: a first beam portion protruding from the base portion; and a second beam portion protruding from the base portion such that a projected position of a front end portion of the second beam portion along a protruding direction of the first beam portion is relatively deviated from a root position of the second beam portion.

(4) In the above invention, a front end area which is positioned at nearer side to a front end than the beam bent portion in the second beam portion may be positioned on an extended line from the first beam portion.

(5) In the above invention, the plurality of conductive patterns may include: a first conductive pattern formed on a surface of the first beam portion; and a second conductive pattern formed on a surface of the second beam portion, and a front end portion of the first conductive pattern and a front end portion of the second conductive pattern may be positioned on a same virtual straight line along the protruding direction of the first beam portion in planer view.

(6) In the above invention, the base portion may have a base bent portion which is bent.

(7) In the above invention, the base portion may have: a first area from which the beam portions protrude in a first direction; and a second area from which the beam portions protrude in a second direction which is different from the first direction, and the base bent portion may interpose between the first area and the second area.

(8) In the above invention, the base portion may have a through hole which is connected with a rear end portion of the conductive pattern and penetrates the base portion.

(9) The probe according to the present invention is a probe which contacts terminals of an electronic device under test, the probe characterized by comprising: a single base portion; a plurality of beam portions whose rear end sides are supported by the base portion and whose front end sides protrude from the base portion; and a plurality of conductive patterns formed on surfaces of the beam portions.

(10) The probe card according to the present invention is characterized by comprising: the above probe; and a board on which the contactor is mounted.

(11) The electronic device testing apparatus according to the present invention is characterized by comprising: the above probe card; a test head to which the probe card is electrically connected; and a tester electrically connected to the test head.

### Advantageous Effect of the Invention

According to the present invention, the beam portion has the beam bent portion, thereby it is possible to deal with the test for electronic devices having input and output terminals arranged in two-dimensional fashion.

### BRIEF DESCRIPTION OF DRAWINGS

FIG. 1 is a schematic view illustrating an electronic device testing apparatus in a first embodiment of the present invention.

FIG. 2 is a conceptual view illustrating connection relationships among a test head, a probe card and a prober in the first embodiment of the present invention.

FIG. 3 is a cross-sectional view illustrating the probe card in the first embodiment of the present invention.

FIG. 4 is a partial plan view of the probe card in the first embodiment of the present invention seen from below.

FIG. 5 is a plan view illustrating the probe in the first embodiment of the present invention.

FIG. 6 is a side elevational view illustrating the probe in the first embodiment of the present invention.

FIG. 7 is a plan view illustrating a probe in a second embodiment of the present invention.

FIG. 8 is a plan view illustrating a probe in a third embodiment of the present invention.

FIG. 9 is a plan view illustrating a probe in a fourth embodiment of the present invention.

FIG. 10 is a plan view illustrating a probe in a fifth embodiment of the present invention.

FIG. 11 is a plan view illustrating a probe in a sixth embodiment of the present invention.

FIG. 12 is a plan view illustrating a probe in a seventh embodiment of the present invention.

FIG. 13 is a cross-sectional view along line A-A in FIG. 4.

FIG. 14 is a cross-sectional view along line B-B in FIG. 4.

FIG. 15 is a cross-sectional view of a probe in an eighth embodiment of the present invention.

FIG. 16 is a cross-sectional view of an SOI wafer illustrating a first step of a method of producing the probe in the first embodiment of the present invention.

FIG. 17 is a bottom plan view of the SOI wafer seen from below at a second step of the method of producing the probe in the first embodiment of the present invention.

FIG. 18 is a cross-sectional view along C-C line in FIG. 17.

FIG. 19 is a cross-sectional view of the SOI wafer illustrating a third step of the method of producing the probe in the first embodiment of the present invention.

FIG. 20 is a cross-sectional view of the SOI wafer illustrating a fourth step of the method of producing the probe in the first embodiment of the present invention.

FIG. 21 is a plan view of the SOI wafer seen from above at a fifth step of the method of producing the probe in the first embodiment of the present invention.

FIG. 22 is a cross-sectional view along line D-D in FIG. 21.

FIG. 23 is a cross-sectional view of the SOI wafer illustrating a sixth step of the method of producing the probe in the first embodiment of the present invention.

FIG. 24 is a plan view of the SOI wafer illustrating a seventh step of the method of producing the probe in the first embodiment of the present invention.

FIG. 25 is a cross-sectional view along line E-E in FIG. 24.

FIG. 26 is a cross-sectional view of the SOI wafer illustrating an eighth step of the method of producing the probe in the first embodiment of the present invention.

FIG. 27 is a cross-sectional view of the SOI wafer illustrating a ninth step of the method of producing the probe in the first embodiment of the present invention.

FIG. 28 is a cross-sectional view of the SOI wafer illustrating a tenth step of the method of producing the probe in the first embodiment of the present invention.

FIG. 29 is a cross-sectional view of the SOI wafer illustrating an 11th step of the method of producing the probe in the first embodiment of the present invention.

FIG. 30 is a plan view of the SOI wafer illustrating a 12th step of the method of producing the probe in the first embodiment of the present invention.

FIG. 31 is a cross-sectional view along line F-F in FIG. 30.

FIG. 32 is a cross-sectional view of the SOI wafer illustrating a 13th step of the method of producing the probe in the first embodiment of the present invention.

FIG. 33 is a plan view of the SOI wafer illustrating a 14th step of the method of producing the probe in the first embodiment of the present invention.

FIG. 34 is a cross-sectional view along line G-G in FIG. 33.

FIG. 35 is a cross-sectional view of the SOI wafer illustrating a 15th step of the method of producing the probe in the first embodiment of the present invention.

FIG. 36 is a plan view of the SOI wafer illustrating a 16th step of the method of producing the probe in the first embodiment of the present invention.

FIG. 37 is a cross-sectional view along line H-H in FIG. 36.

FIG. 38 is a plan view of the SOI wafer illustrating a 17th step of the method of producing the probe in the first embodiment of the present invention.

FIG. 39 is a cross-sectional view along line I-I in FIG. 38.

FIG. 40 is a cross-sectional view of the SOI wafer illustrating an 18th step of the method of producing the probe in the first embodiment of the present invention.

FIG. 41 is a plan view of the SOI wafer illustrating a 19th step of the method of producing the probe in the first embodiment of the present invention.

FIG. 42 is a cross-sectional view along line J-J in FIG. 41.

FIG. 43 is a plan view of the SOI wafer illustrating a 20th step of the method of producing the probe in the first embodiment of the present invention.

FIG. 44 is a cross-sectional view along line K-K in FIG. 43.

FIG. 45 is a cross-sectional view of the SOI wafer illustrating a 21st step of the method of producing the probe in the first embodiment of the present invention.

FIG. 46 is a cross-sectional view of the SOI wafer illustrating a 22nd step of the method of producing the probe in the first embodiment of the present invention.

FIG. 47 is a plan view of the SOI wafer illustrating a 23rd step of the method of producing the probe in the first embodiment of the present invention.

FIG. 48 is a cross-sectional view along line L-L in FIG. 47.

FIG. 49 is a cross-sectional view of the SOI wafer illustrating a 24th step of the method of producing the probe in the first embodiment of the present invention.

FIG. 50 is a plan view of the SOI wafer illustrating a 25th step of the method of producing the probe in the first embodiment of the present invention.

FIG. 51 is a cross-sectional view along line M-M in FIG. 50.

FIG. 52 is a cross-sectional view of the SOI wafer illustrating a 26th step of the method of producing the probe in the first embodiment of the present invention.

FIG. 53 is a plan view of the SOI wafer illustrating a 27th step of the method of producing the probe in the first embodiment of the present invention.

FIG. 54 is a cross-sectional view along line N-N in FIG. 53.

FIG. 55 is a cross-sectional view of the SOI wafer illustrating a 28th step of the method of producing the probe in the first embodiment of the present invention.

FIG. 56 is a cross-sectional view of the SOI wafer illustrating a 29th step of the method of producing the probe in the first embodiment of the present invention.

FIG. 57 is a bottom plan view of the SOI wafer illustrating a 30th step of the method of producing the probe in the first embodiment of the present invention.

FIG. 58 is a cross-sectional view along line O-O in FIG. 57.

FIG. 59 is a cross-sectional view of the SOI wafer illustrating a 31st step of the method of producing the probe in the first embodiment of the present invention.

FIG. 60 is a cross-sectional view of the SOI wafer illustrating a 32nd step of the method of producing the probe in the first embodiment of the present invention.

### EMBODIMENTS FOR CARRYING OUT THE INVENTION

Hereinafter, embodiments according to the present invention will be described with reference to the drawings.

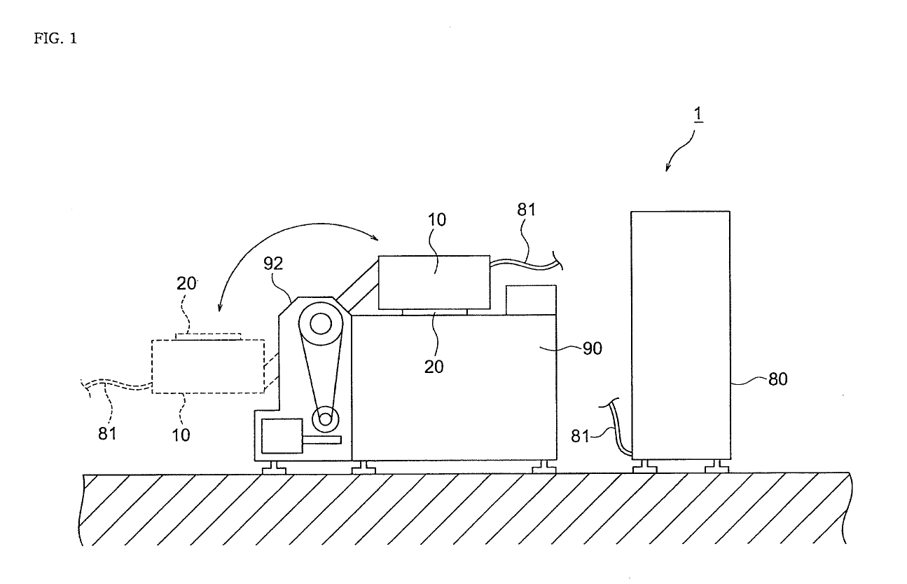

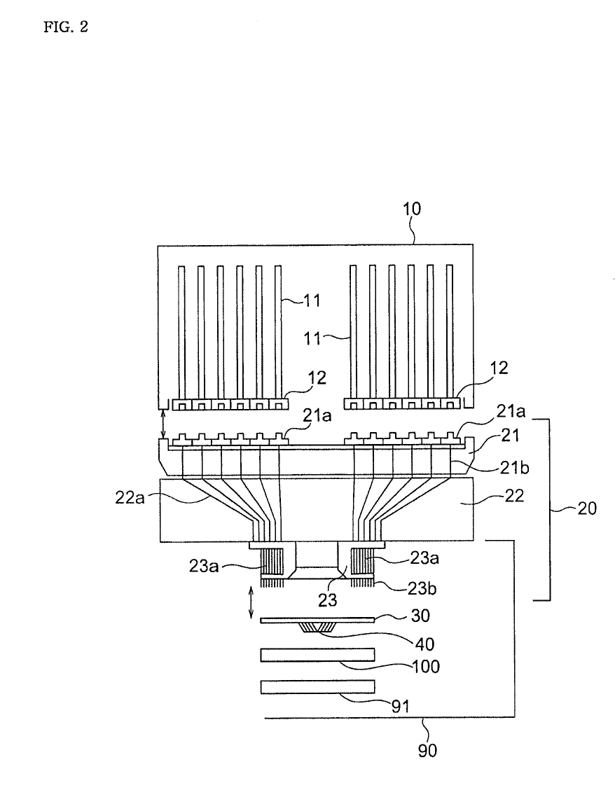

FIG. 1 is a schematic view illustrating an electronic device testing apparatus in a first embodiment of the present invention, and FIG. 2 is a conceptual view illustrating connection relationships among a test head, a probe card and a prober in the first embodiment of the present invention.

As shown in FIG. 1 and FIG. 2, the electronic device testing apparatus 1 in the first embodiment of the present invention comprises a test head 10, a tester 80 and a prober 90. The tester 80 is electrically connected via a cable bundle 81 to the test head 10 and thereby capable of inputting and outputting test signals for DUTs formed on a silicon wafer 100 under test. The test head 10 is to be disposed above the prober 90 by a manipulator 92.

A number of pin electronics 11 are provided in the test head 10 and these pin electronics 11 are connected to the tester 80 via the cable bundle 81 having several hundred internal cables. In addition, the pin electronics 11 are mounted thereon with respective connectors 12 for connecting to a mother board 21, thereby capable of being electrically connected with contact terminals 21a on the mother board 21 of an interface section 20.

The test head 10 and the prober 90 are connected via the interface section 20. The interface section 20 comprises the mother board 21, a wafer performance board 22 and a frog ring 23. The mother board 21 is provided thereon with the contact terminals 21a for electrically connecting with the connectors 12 on the side of the test head 10 and is further formed thereon with wiring patterns 21b for electrically connecting these contact terminals 21a and the wafer performance board 22. The wafer performance board 22 is electrically connected with the mother board 21 via pogo pins and the like, and wiring patterns 22a are formed to convert the pitch of the wiring patterns 21b on the mother board 21 to the pitch of the frog ring 23 side.

The frog ring 23 is provided on the wafer performance board 22, and the internal transmission paths thereof consist of flexible boards 23a in order to allow an alignment between the test head 10 and the prober 90. A number of pogo pins 23b which have been electrically connected with these flexible boards 23a are mounted on the lower surface of the frog ring 23.

Probe card 30 on which a number of probes 40 are mounted is electrically connected with the frog ring 23 via the pogo pins 23b. Although not particularly shown, the probe card 30 is fixed to a top plate of the prober 90 via a holder, and the probes 40 are to approach the inside of the prober 90 through an opening of the top plate.

The prober 90 is capable of suction holding a semiconductor wafer 100 under test on a chuck 91 and then automatically supplying that wafer 100 to a position facing the probe card 30.

According to the electronic device testing apparatus 1 configured in such a manner, the prober 90 presses the semiconductor wafer 100 under test held on the chuck 91 against the probe card 30 so as to electrically contact the probes 40 and input and output terminals 110 of DUTs formed on the semiconductor wafer 100 under test, while in this status the tester 80 applies DC signals and digital signals to those DUTs and receives output signals from those DUTs. Ultimately, the tester 80 compares the output signals (response signals) from those DUTs with expected values thereby to evaluate the electrical characteristics of those DUTs.

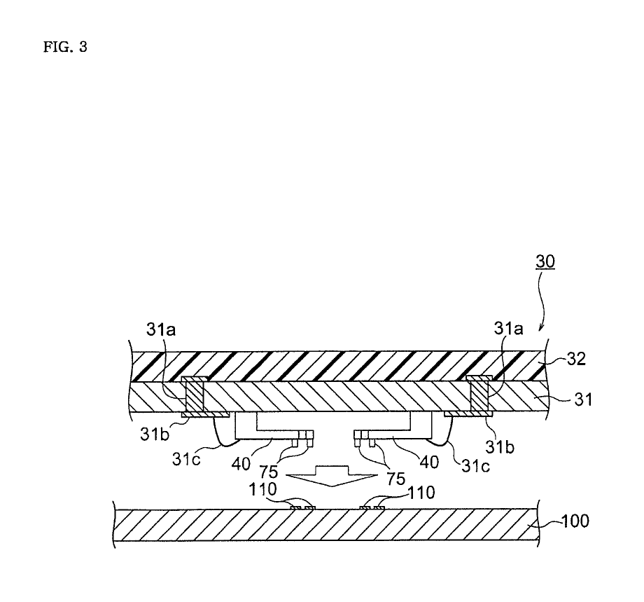

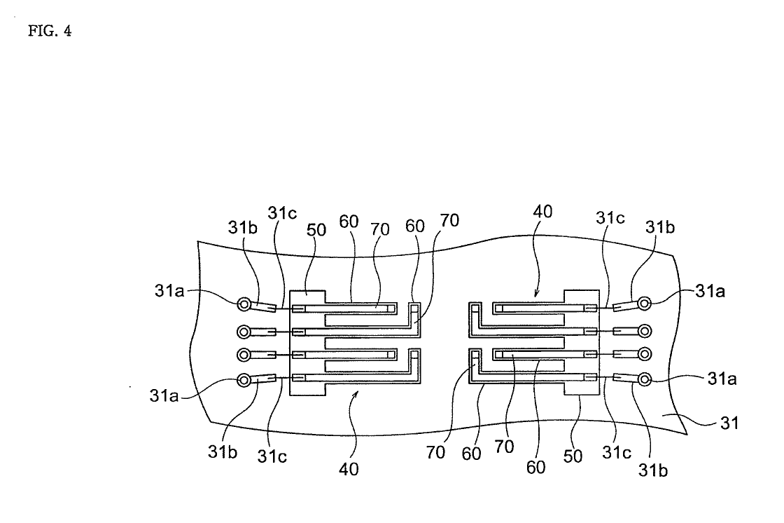

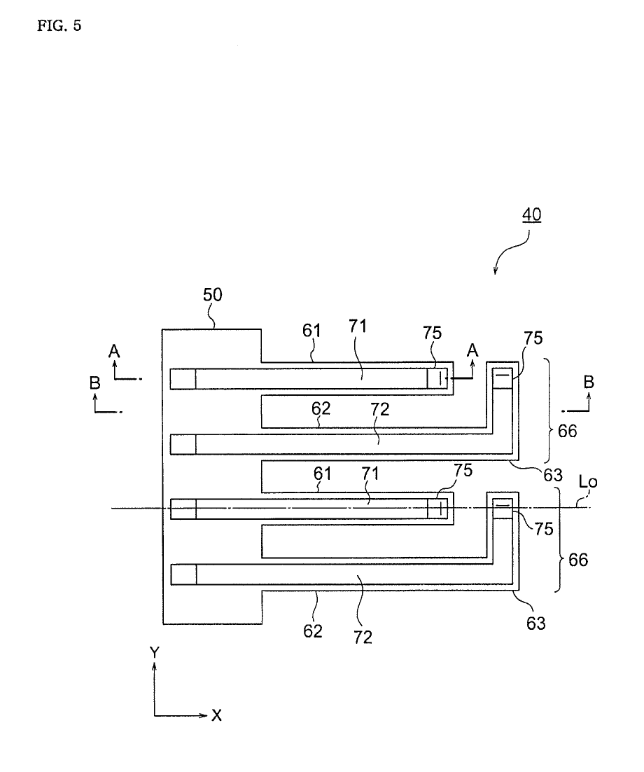

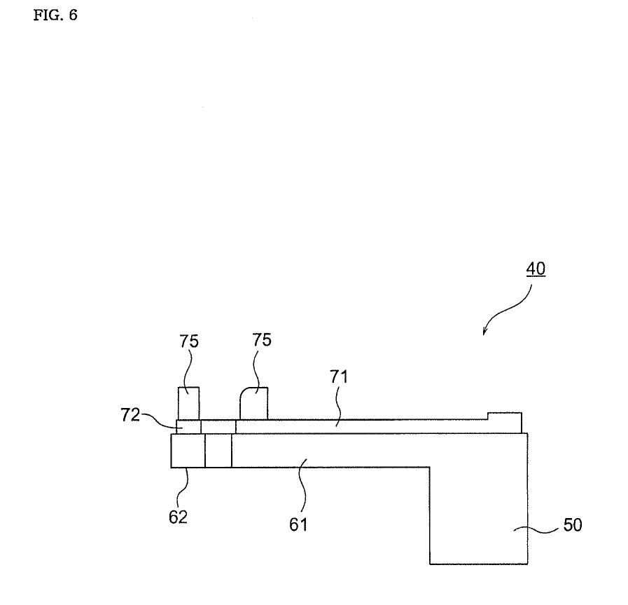

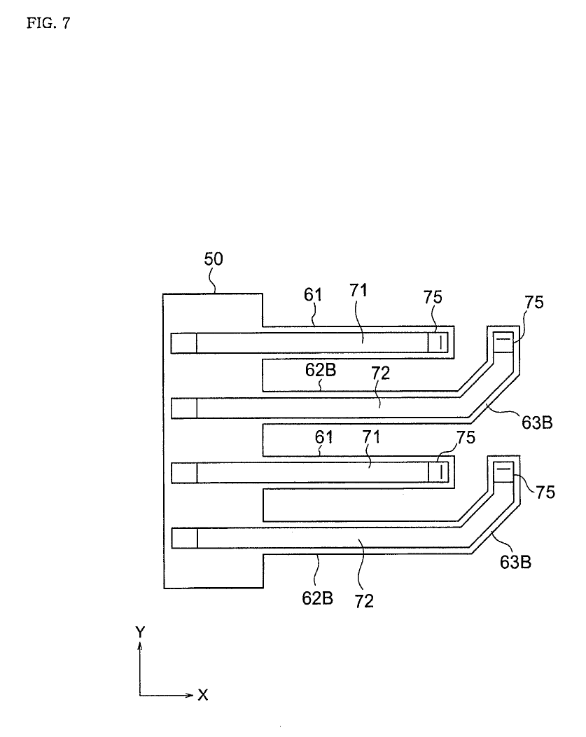

FIG. 3 and FIG. 4 are respectively a cross-sectional view and a partial plan view illustrating the probe card in the first embodiment of the present invention, FIG. 5 and FIG. 6 are respectively a plan view and a cross-sectional view illustrating the probe in the first embodiment of the present invention, and FIG. 7 to FIG. 12 are plan views illustrating probes respectively in a second to seventh embodiments of the present invention.

As shown in FIG. 3 and FIG. 4, the probe card 30 in the present embodiment comprises: a probe board 31 configured of a multilayer wiring board or the like, for example; a stiffener 32 attached to the top surface of the probe board 31 in order to reinforce the mechanical strength; and a number of probes 40 mounted on the lower surface of the probe board 31.

Through holes 31a which penetrate from the lower surface to the upper surface are formed in the probe board 31, and connection traces 31b which are connected with through holes 31 a are formed on the lower surface.

The probes 40 in the present embodiment are contactors which contact with the input and output terminals 110 of DUTs in order to establish electrical connections between those DUTs and the test head 10 at the test of DUTs. These probes 40 are fixed on the probe board 31 by means of adhesive and the like and electrically connected with the connection traces 31b via bonding wires 31c.

As shown in FIG. 5 and FIG. 6, each probe 40 comprises: a single base portion 50 fixed to the probe board 31; four beam portions 60 whose rear end sides are supported by the base portion 50 and whose front end sides protrude from the base portion 50; and four conductive patterns 70 formed on respective surfaces of the beam portions 60. Note that the number of the beam portions 60 supported by the single base portion 50 is not particularly limited and five or more beam portions 60 may protrude from one base portion 50, for example.

The beam portions 60 in the present embodiment involve two kinds of beam portions, which include: first beam portions 61 linearly extending from the base portion 50 along the X-direction; and second beam portions 62 also linearly extending from the base portion 50 along the X-direction and having beam bent portions 63. Note that the beam portions 60 may alternatively consist of second beam portions 62 only or may include beam portions with other shapes. Note also that reference numerals 60 in the present embodiment denote collectively the first beam portions 61 and the second beam portions 62.

In addition, the conductive patterns 70 are formed on respective surfaces of the beam portions 60. The conductive patterns 70 in the present embodiment involve two kinds of conductive patterns, which include: first conductive patterns 71 formed on the surfaces of the first beam portions 61; and second conductive patterns 72 formed on the surfaces of the second beam portions 62. Note that reference numerals 70 in the present embodiment denote collectively the first conductive patterns 71 and the second conductive patterns 72.

Contact portions 75 which project in convex shapes are formed at front end of both the conductive patterns 71 and 72. These contact portions 75 contact with the input and output terminals 110 of DUTs formed on a semiconductor wafer 100 under test during the testing of those DUTs. Note that the shape of the contact portions 75 is not particularly limited so long as projecting in a convex shape.

As shown in FIG. 5, two first beam portions 61 and two second beam portions 62 are alternately protruding from the base portion 50 with substantially equal spaces. Further, in the present embodiment, each second beam portion 62 is bent at its beam bent portion 63 toward the Y-direction, and the front end area 66 at nearer side to the front end than the beam bent portion 63 in that second beam portion 62 approaches the front end of the first beam portion 61 so as to be positioned on the extended line from the first beam portion 61. More specifically, in the present embodiment, as shown in the same figure, the front end portion (contact portion 75) of first conductive pattern 71 and the front end portion (contact portion 75) of the second conductive pattern 72 are positioned on the same virtual straight line L₀ along the X-direction. Note that the second beam portions 62 are ensured to have the same loading characteristics as the first beam portions 61 by adjusting the width and/or the thickness of the second beam portions 62 because the length of the second beam portions 62 is different from that of the first beam portions 61.

Thus, according to the present embodiment, the second beam portions 62 are formed with the beam bent portions 63 thereby to allow to deal with the testing of DUTs having input and output terminals 110 arranged in two-dimensional fashion.

In addition, according to the present embodiment, a plurality of beam portions 60 are supported by the single base portion 50 while the relative positional relationships among the contact portions 75 are accurately defined, and therefore it is possible to accurately press the contact portions 75 to the input and output terminals 110 arranged in two-dimensional fashion.

Beside that, as the pitch between the input and output terminals 110 of DUTs progresses to be narrowed, problems generally occur including that the mounting strength of the probes to the probe board is reduced. In contrast, according to the present embodiment, a plurality of beam portions 60 are supposed by the single base portion 50, and the contact area of the probes 40 with the probe board 31 is thus ensured to be large thereby capable of improving the mounting strength of the probes 40.

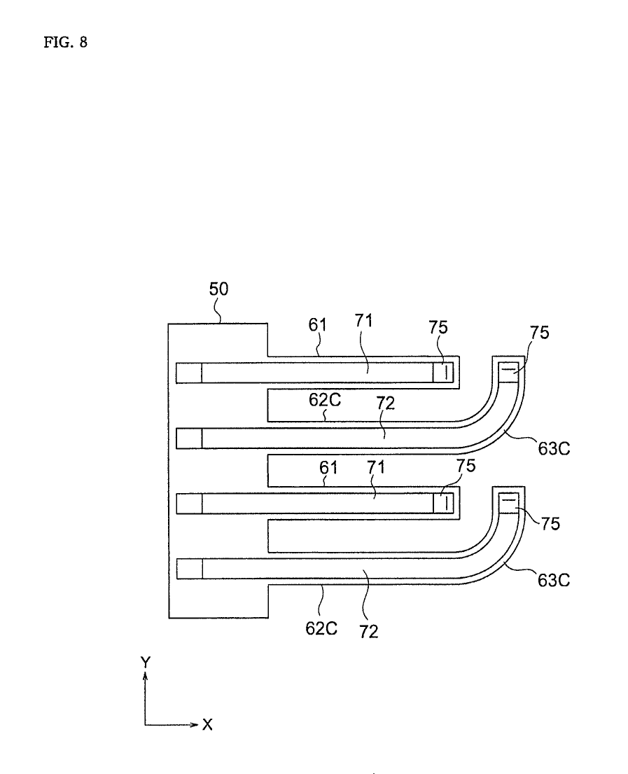

Alternatively, such as second beam portions 62B shown in FIG. 7, beam bent portions 63B may be bent so as to be inclined to the X-direction of the same figure in planer view. Still alternatively, such as second beam portions 62C shown in FIG. 8. beam bent portions 63C may be bent in a curved fashion in planer view.

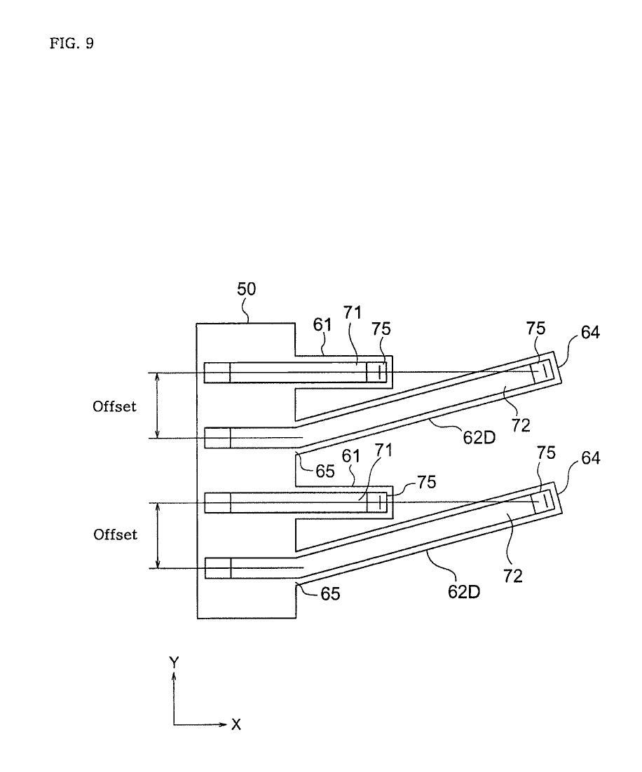

In addition, it is enough that a projected positions of the front end portions 64 of the second beam portions 62 along the X-direction are relatively offset from the root portions 65. For example, as shown in FIG. 9, the whole of the second beam portions 62D may be inclined to the X-direction from the root portions 65 at which the second beam portions 62D protrude from the base portion 50.

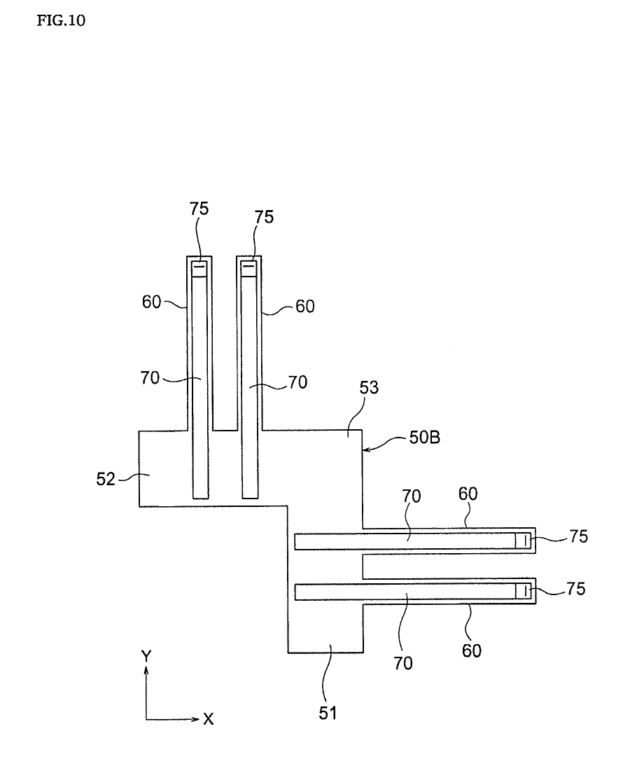

Alternatively, as shown in FIG. 10, base portion 50B may be provided with a base bent portion 53, and beam portions 60 may protrude from the first area 51 in the X-direction while beam portions 60 may protrude from the second area 52 in the Y-direction. Providing such base bent portions 53 ensures large contact area of the probes 40 to the probe board 31 thereby improving the mounting strength of the probes 40. Moreover, employing the configuration as shown in FIG. 10 allows one probe 40 to deal with a plurality of DUTs.

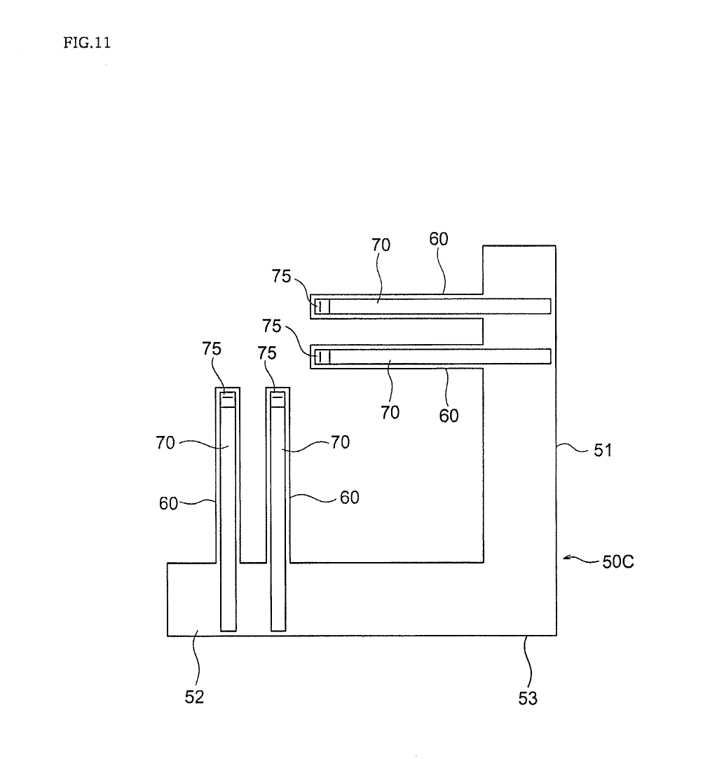

Yet alternatively, such as base portion 50C shown in FIG. 11, beam portions 60 protruding from the first area 51 and beam portions 60 protruding from the second area 52 protrude in such directions that they come close to each other. This allows the mounting strength of the probes 40 to be improved. Note that the base bent portion 53 may be bent at an angle other than the right angle or bent in a curved manner. Note also that one base portion may be provided with a plurality of bent portions 53.

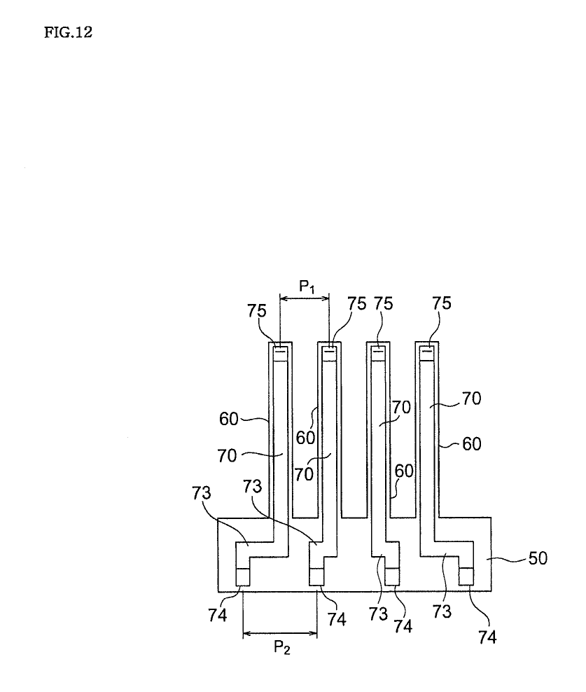

Still alternatively, as shown in FIG. 12, conductive patterns 70 may be provided with pattern bent portions 73, so that the pitch P₂ between the rear end portions 75 of the conductive patterns 70 may be wider in comparison with the pitch P₁ between the front end portions (contact portions 75) of the conductive patterns 70. Thereby, it is possible to further narrow the pitch of probe 40.

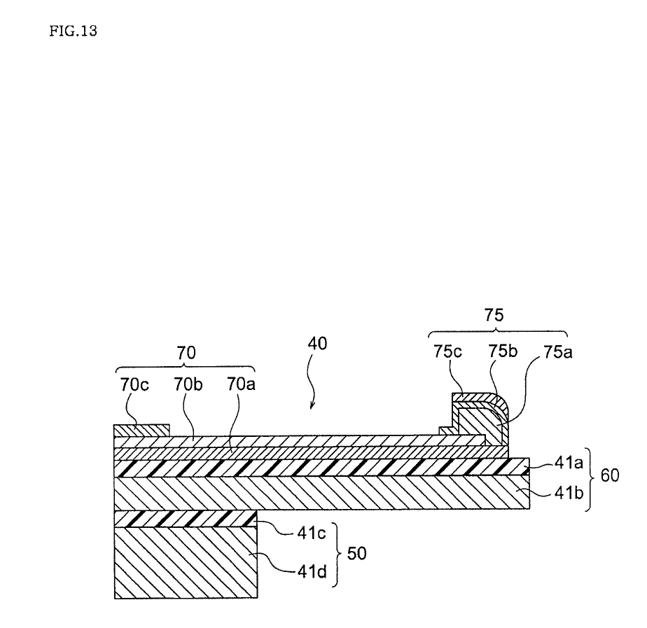

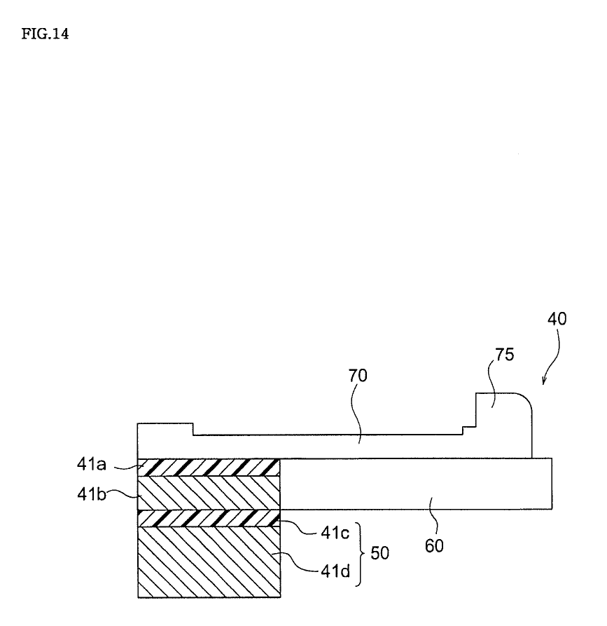

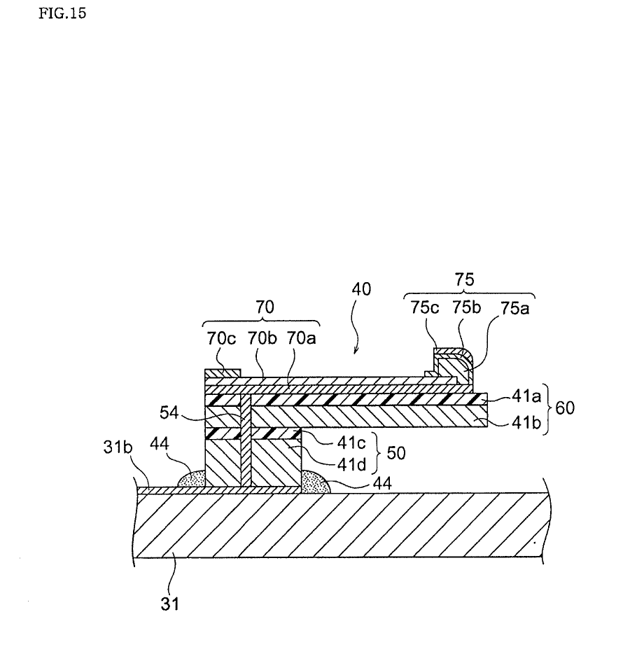

Then the internal structure of the probes 40 will be described. FIG. 13 and FIG. 14 are cross-sectional views of a probe in embodiments of the present invention, and FIG. 15 is a cross-sectional view of a probe in the eighth embodiment of the present invention.

The probes 40 in the present embodiment are produced by applying semiconductor manufacturing techniques, such as photolithography, to a silicon wafer 41, as will be described later. As shown in FIG. 13 and FIG. 14, base portion 50 comprises: a support layer 41d composed of silicon (Si); and a BOX layer 41c stacked on the support layer 41d and composed of silicon oxide (SiO₂). On the other hand, each of the beam portions 60 comprises: an active layer 41b composed of silicon (Si); and a first SiO₂ layer 41a stacked on the active layer 41b and acting as an insulation layer.

In addition, each conductive pattern 70 is formed on the insulation layer (first SiO₂ layer) 41a. As shown in the same figures, the conductive pattern 70 comprises: a seed layer (power supplying layer) 70a composed of titanium and gold; a first conductive layer 70b stacked on the seed layer 70a and composed of gold; and a second conductive layer 70c provided at the rear end of the first conductive layer 70b and composed of highly pure gold.

Further, each contact portion 75 is formed on the front end of the conductive pattern 70 so as to protrude upward. This contact portion 75 comprises: a first contact layer 75a formed on a step consisting of the seed layer 70a and the first conductive layer 70b; a second contact layer 75b provided to envelop the first contact layer 75a and composed of gold; and a third contact layer 75c provided to envelop the second contact layer 75b.

As materials for composing the first contact layer 75a, nickel or nickel alloys such as nickel cobalt may be mentioned. Further, as materials for composing the third contact layer 75c, rhodium, platinum, ruthenium, palladium, iridium, or alloys thereof may be mentioned.

As shown in FIG. 3 and FIG. 4, probes 40 configured in such a manner are mounted on the probe board 31 so that the contact portions 75 face respective input and output terminals 110 on a semiconductor wafer 100 under test. Note that, although only two probes 40 are shown in FIG. 3 and FIG. 4, several hundred to several thousand of probes 40 are actually mounted on one probe board 31.

Each probe 40 is fixed at the lower surface of the base portion 50 to the probe board 31 using adhesive and the like. As such adhesive, for example, ultraviolet curable type adhesive, thermally curable type adhesive, or thermoplastic adhesive etc. may be mentioned.

Further, bonding wires 31c which are connected with connection traces 31b are connected to the second conductive layers 70c of the conductive patterns 70, and the conductive patterns 70 of the probes 40 and the connection traces 31b of the probe board 31 are thus electrically connected via these bonding wires 31c.

The testing of DUTs employing such a configuration of the probe card 30 is performed by pressing a semiconductor wafer 100 under test against the probe card 30 using the prober 90 so as to electrically contact the probes 40 on the probe board 31 and the input and output terminals 110 of the semiconductor wafer 100 under test with each other and by inputting/outputting test signals from tester 80 to those DUTs in this status.

Note that the probes 40 may be mounted on the probe board 31 in a status of being inclined, and in this case the contact portions 75 may not be formed on the front ends of the conductive patterns 70.

Note also that a circuit board to be electrically connected with the probes 40 may alternatively be configured as an independent member from a probe board to which the probes 40 are to be mechanically fixed. In this case, the probes 40 and the circuit board are electrically connected via bonding wires which are inserted in penetrating holes formed in the probe board.

Note further that, as shown in FIG. 15, a through hole 54 may be formed in the probe 40 so as to penetrate the base portion 50 and the beam portions 60, so the conductive patterns 70 are electrically connected with the connection traces 31b on the probe board 31 via the through hole 54. In this case, the through holes 54 and the connection traces 31b are connected by means of soldering, for example. Further, mold members 44 may be mounded around the connection area between the base portion 50 and the probe board 31 thereby to improve the mounting strength of the corresponding probe 40.

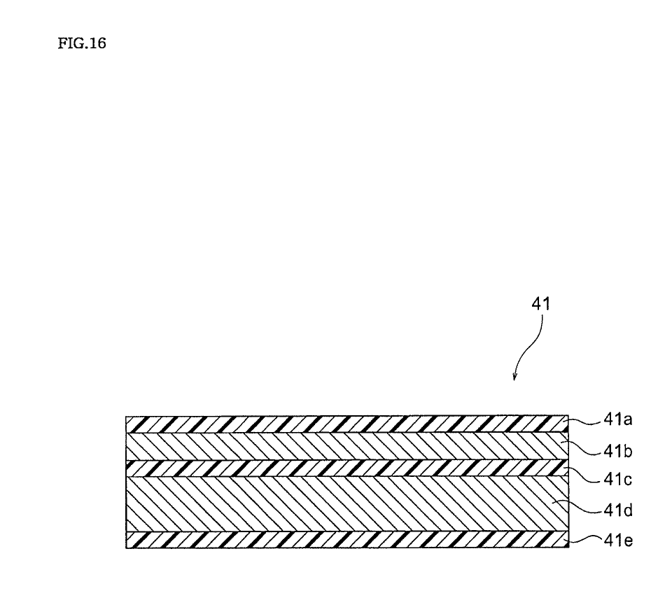

One example of a method of producing the probes in the first embodiment of the present invention will be hereinafter described with reference to FIG. 16 to FIG. 60. FIG. 16 to FIG. 60 are cross-sectional views and plan views of an SOI wafer illustrating each step of the method of producing the probes in the first embodiment of the present invention.

First, in the producing method according to the present embodiment, at a first step shown in FIG. 16, an SOI wafer (Silicon on Insulator wafer) 41 is prepared. This SOI wafer 41 is a silicon wafer which has: two Si layers 41b, 41d; and three SiO₂ layers 41a, 41c, 41e among which the two Si layers 41b, 41d are respectively interposed and stacked. These SiO₂ layers 41a, 41c, 41e of the SOI wafer 41 function as etching stoppers when producing the probes 40 or function as electrically insulating layers.

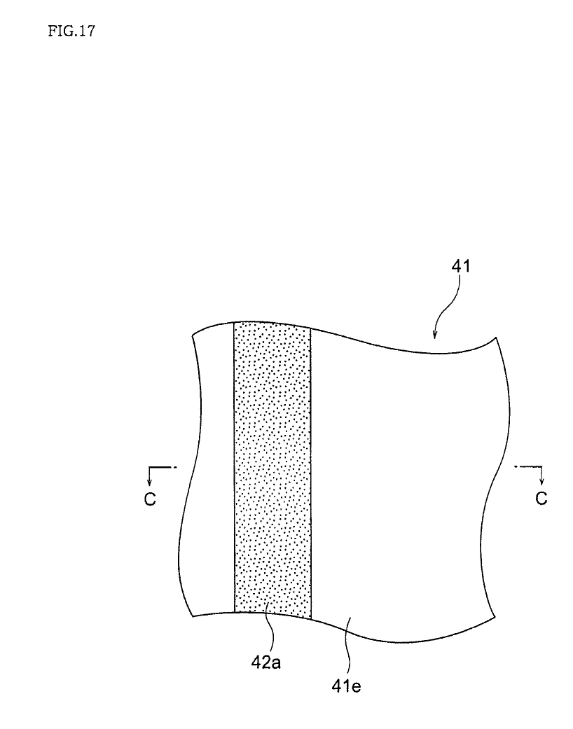

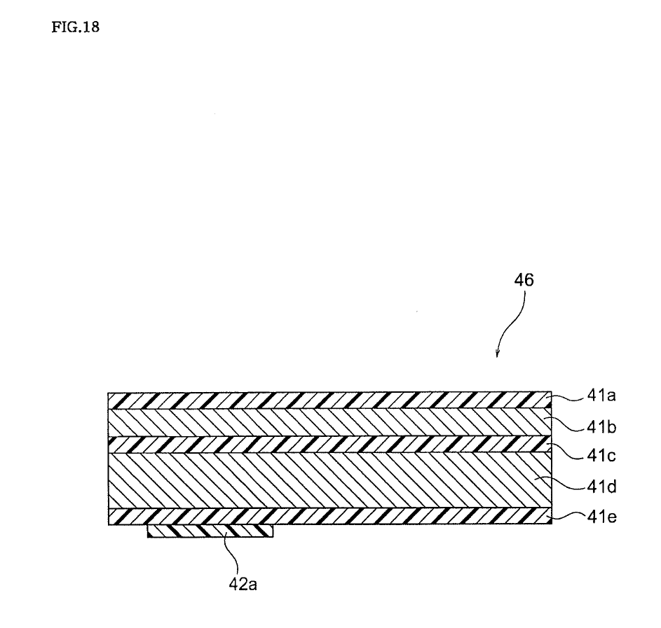

Next, at a second step shown in FIG. 17 and FIG. 18, a first resist layer 42a is formed on the lower surface of the SOI wafer 41. In this step, although not particularly shown, first a photoresist film is formed on the entire surface of the second SiO₂ 41e, then this photoresist film is overlaid with a photomask and exposed by ultraviolet rays to cure (solidify) it in the overlaid state thereby to form the first resist layer 42a on a part of the second SiO₂ layer 41e. Note that the parts of the photoresist film not exposed by the ultraviolet rays are then dissolved and washed away from the second SiO₂ layer 41e.

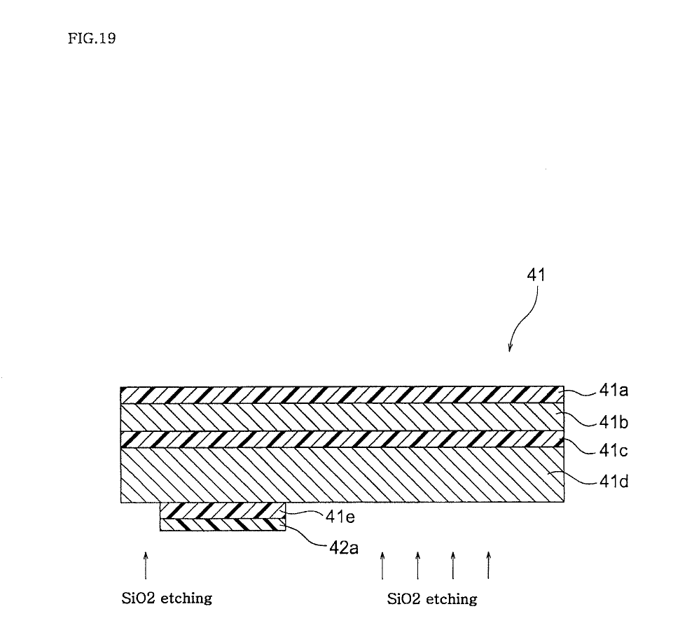

Subsequently, at a third step shown in FIG. 19, an etching process to the second SiO₂ layer 41e from below the SOI wafer 41 is performed using for example RIE (Reactive Ion Etching) and the like. Owing to this etching process, the parts of the second SiO₂ layer 41e not covered with the first resist layer 42a are etched.

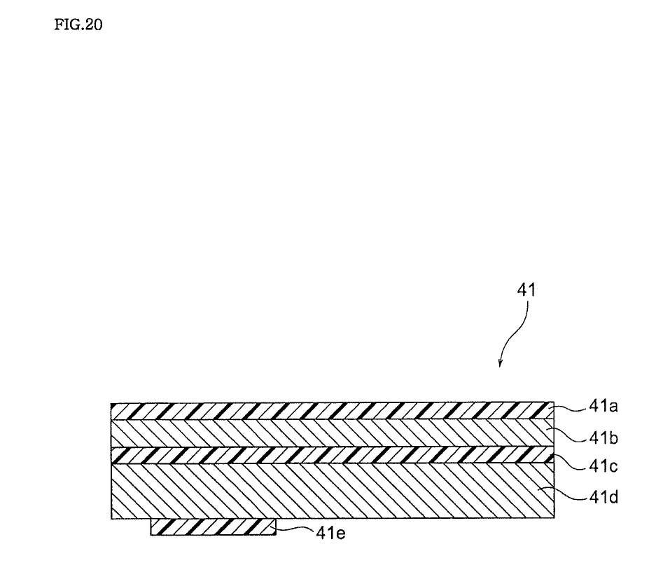

After completing this etching process, at a fourth step shown in FIG. 20, the first resist layer 42a remaining on the second SiO₂ layer 41e is removed (resist peeling). In this resist peeling, oxygen plasma is used for ashing the resist, and washing solution such as sulfuric acid-hydrogen peroxide mixture is then used to wash the SOI wafer 41.

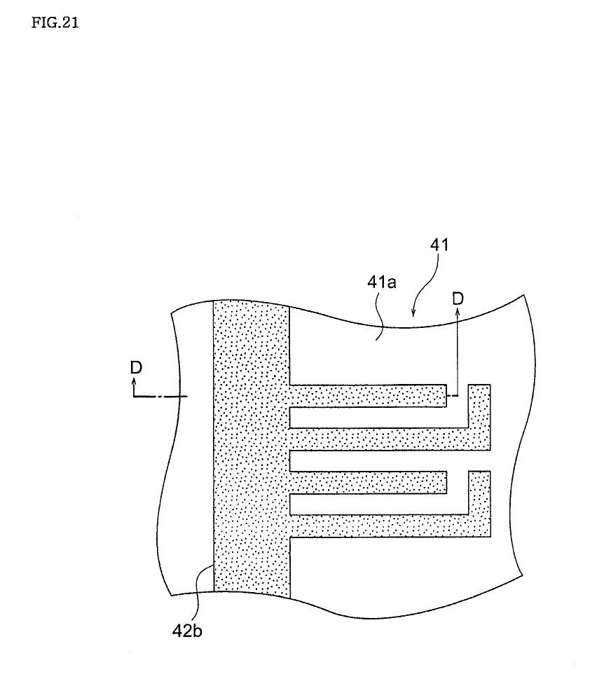

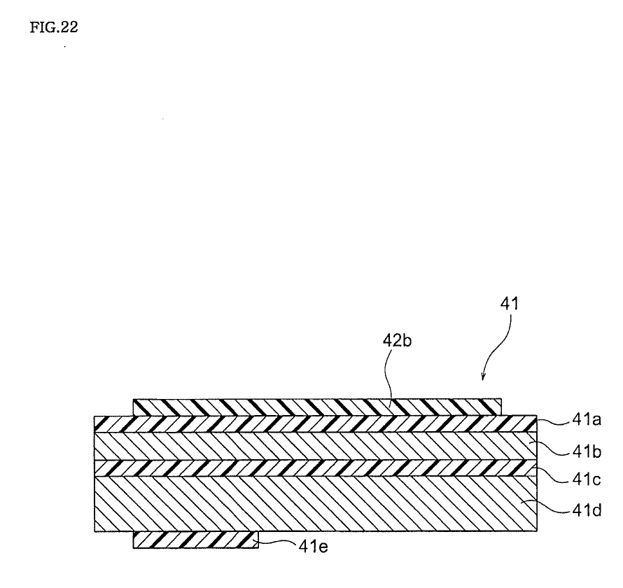

Next, at a fifth step shown in FIG. 21 and FIG. 22, a second resist layer 42b is formed on the surface of the first SiO₂ layer 41a. As shown in FIG. 21, this second resist layer 42b is formed in a shape corresponding to the four beam portions 60 shown in FIG. 5 in a similar manner as the first resist layer 42a described for the second step.

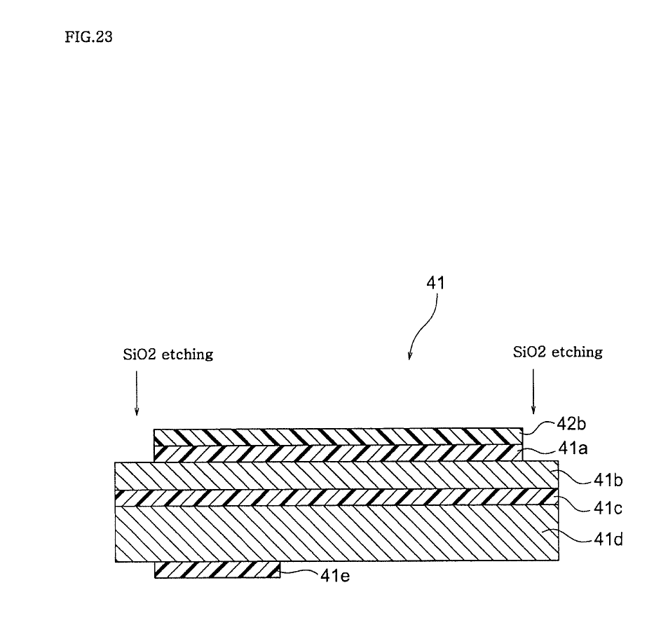

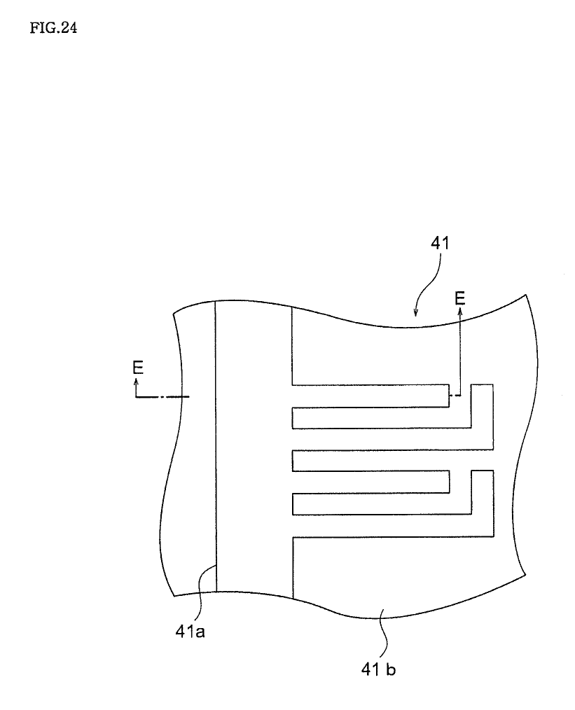

Subsequently, at a sixth step shown in FIG. 23, an etching process to the first SiO₂ layer 41a from above the SOI wafer 41 is performed using for example RIE and the like. Owing to this etching process, the parts of the first SiO₂ layer 41a not covered with the second resist layer 42b are etched, thereby the first SiO₂ layer 41a has the shape corresponding to the four beam portions 60 shown in FIG. 5 (refer to FIG. 24).

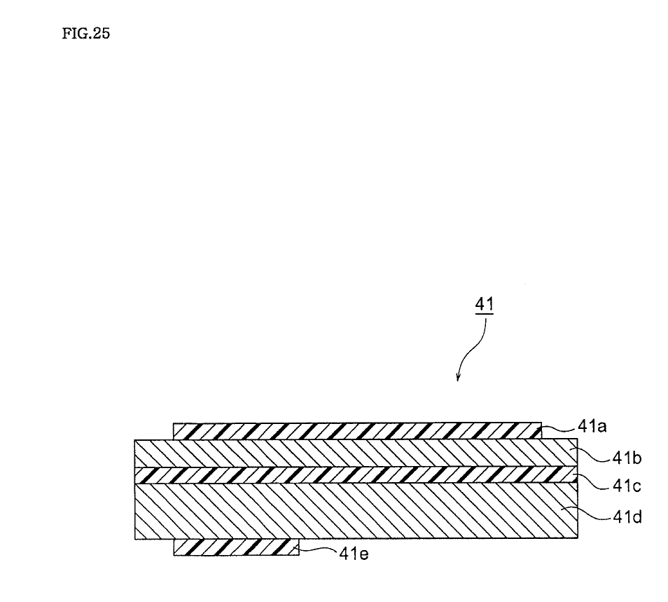

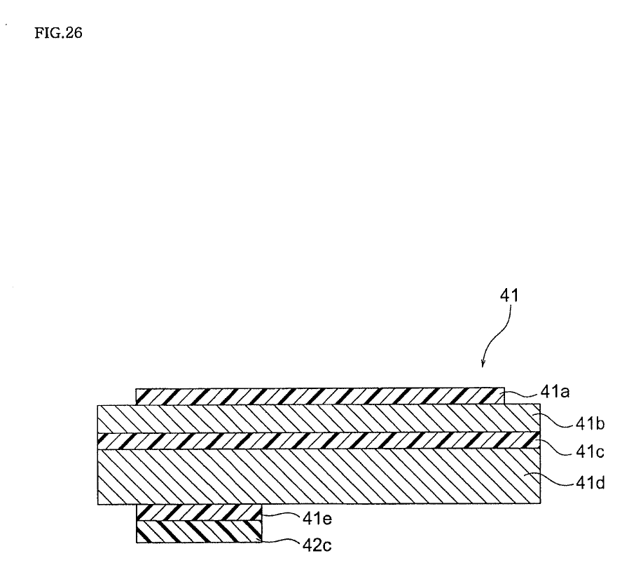

Then, at a seventh step shown in FIG. 24 and FIG. 25, the second resist 42b is removed in a similar manner as the above-described fourth step. Thereafter at an eighth step shown in FIG. 26, a third resist layer 42c is formed on the second SiO₂ layer 41e in the same manner as the above-described second step.

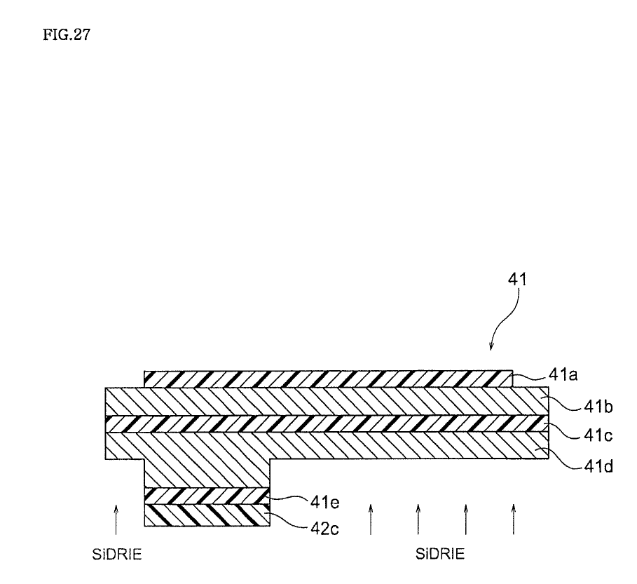

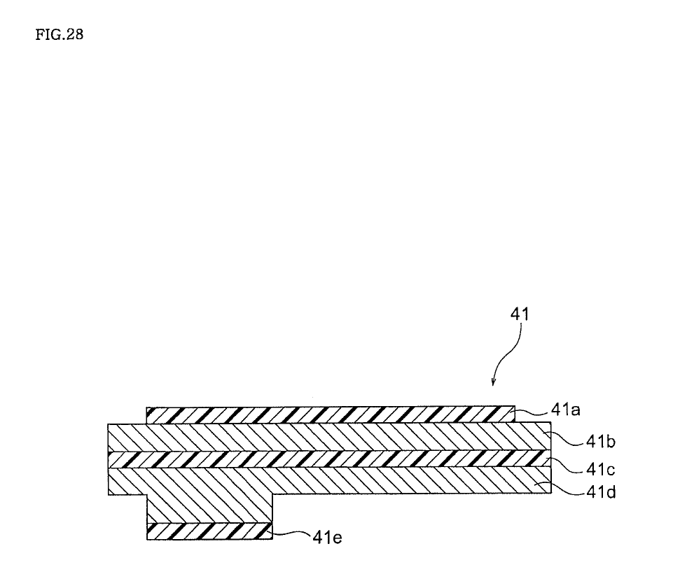

Next, at a ninth step shown in FIG. 27, an etching process to the support layer 41d from below the SOI wafer 41 is performed. Examples of specific method for this etching process may include DRIE (Deep Reactive Ion Etching) method and other methods, for example. Owing to this etching process, the parts of the support layer 41d not covered with the third resist layer 42c are etched to a depth of approximately half of that support layer 41d. Then, at a tenth step shown in FIG. 28, the third resist layer 42c is removed in a similar manner as the above-described fourth step.

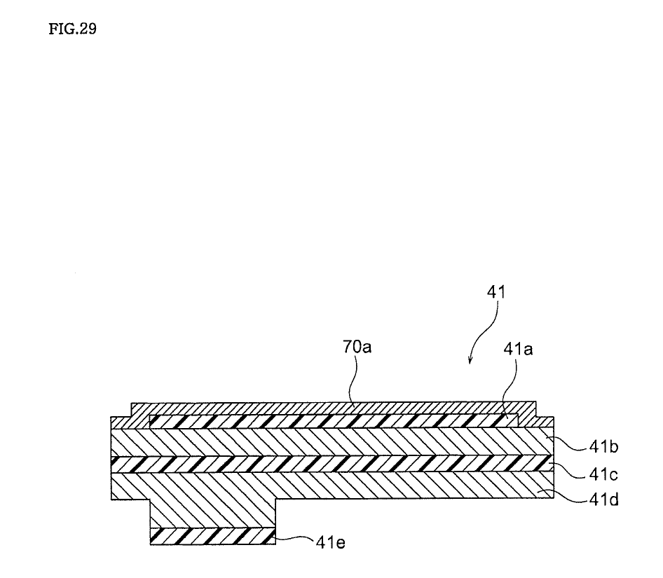

Subsequently, at an 11th step shown in FIG. 29, the seed layer 70a composed of titanium and gold is deposited as a film on the entire upper surface of the SOI wafer 41. Examples of specific method for depositing this seed layer 70a may include vacuum deposition, sputtering, vapor phase deposition and other methods, for example. This seed layer 70a functions as a power supplying layer when forming the first conductive layer 70b.

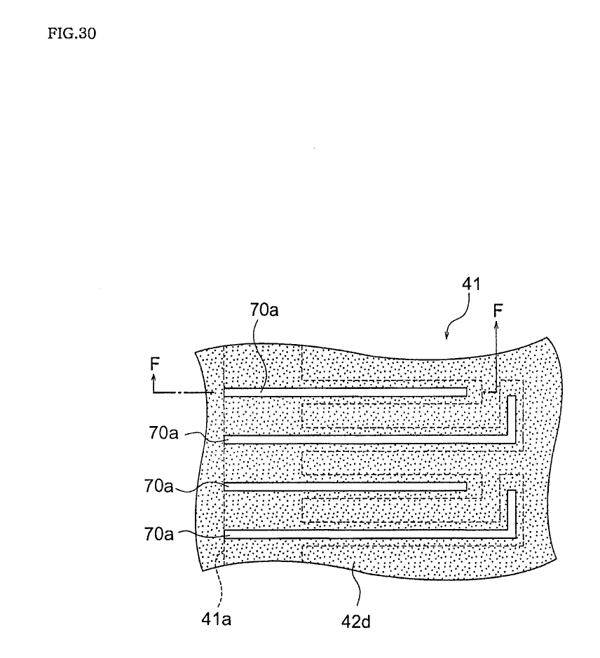

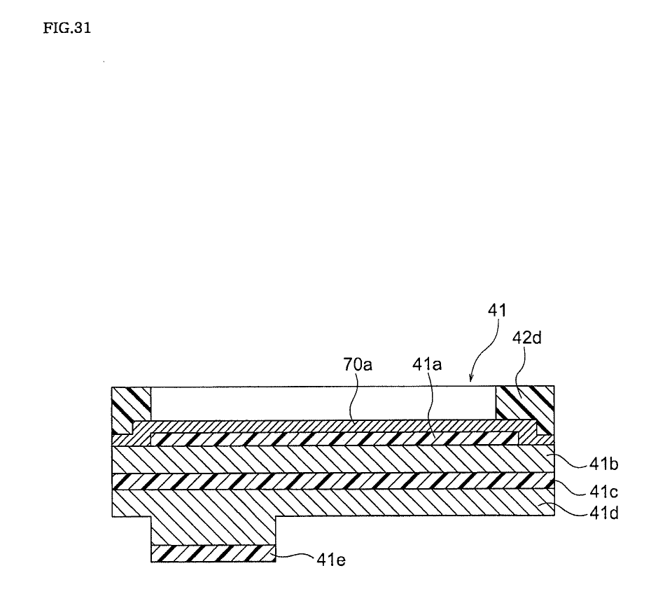

Next, at a 12th step shown in FIG. 30 and FIG. 31, a fourth resist 42d is formed on the surface of the seed layer 70a in a similar manner as the above-described second step. As shown in FIG. 30, this fourth resist 42d is formed on the whole of the seed layer 70a except for the areas to be finally formed thereon with the conductive patterns 70.

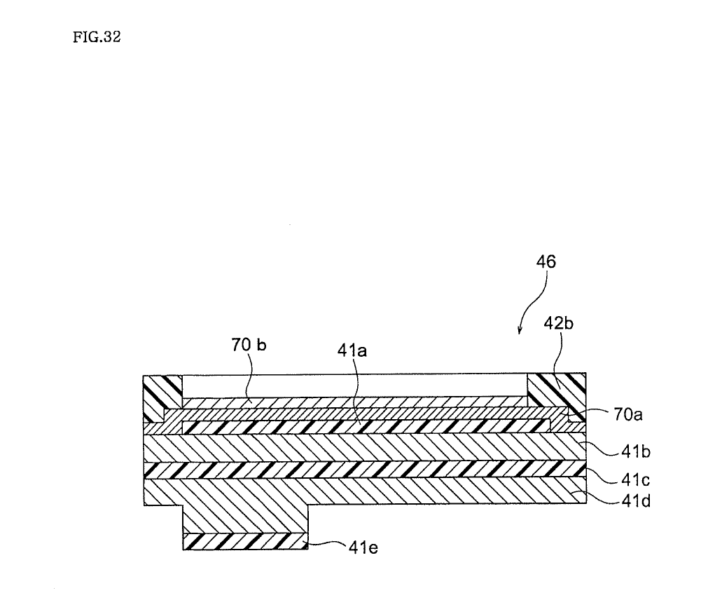

Then, at a 13th step shown in FIG. 32, the first conductive layers 70b is formed by a plating process on the areas of the seed layer 70a not covered with the fourth resist 42d.

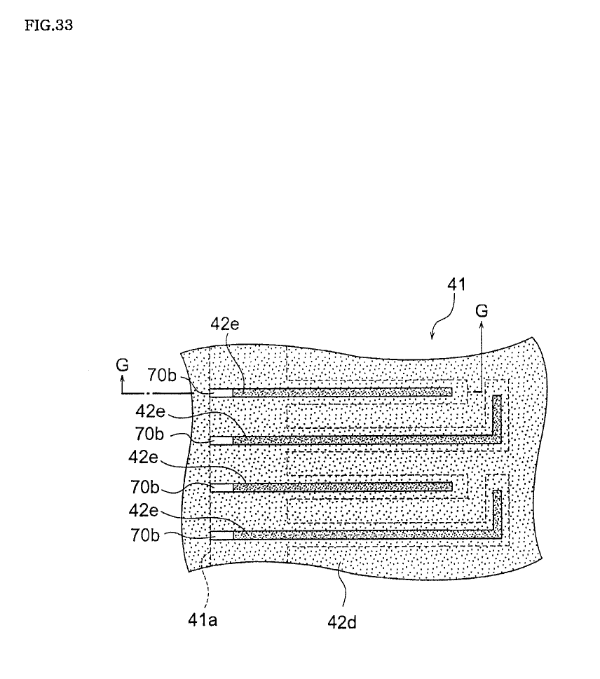

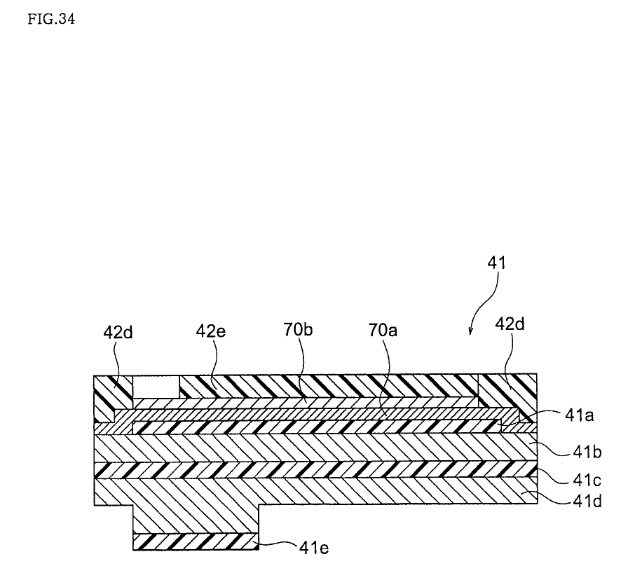

Next, at a 14th step shown in FIG. 33 and FIG. 34, fifth resist layers 42e are formed while in a status where the fourth resist 42d remains on the seed layer 70a. As shown in FIG. 33, these fifth resist layers 42e are formed on the whole of those first conductive layers 70b except for the areas at the rear end sides of those first conductive layers 70b.

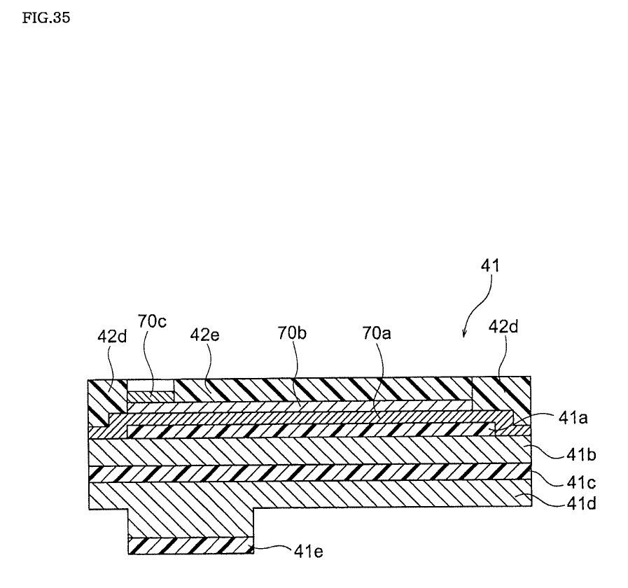

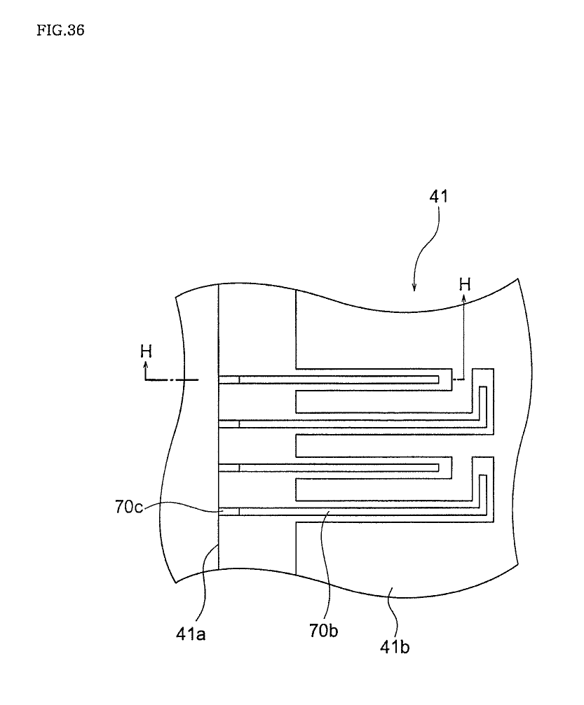

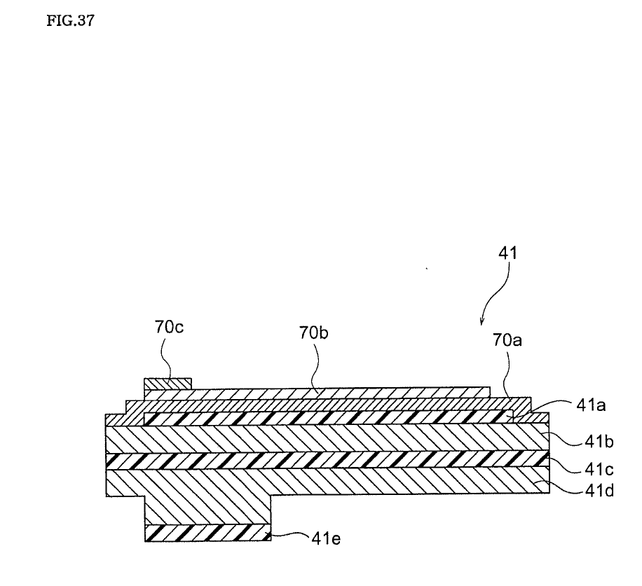

Then, at a 15th step shown in FIG. 35, the second conductive layers 70c are formed by a plating process on the areas within the surfaces of the first conductive layers 70b not covered with the resists 42d, 42e. Thereafter at a 16th step shown in FIG. 36 and FIG. 37, the resists 42d, 42e are removed in a similar manner as the above-described fourth step.

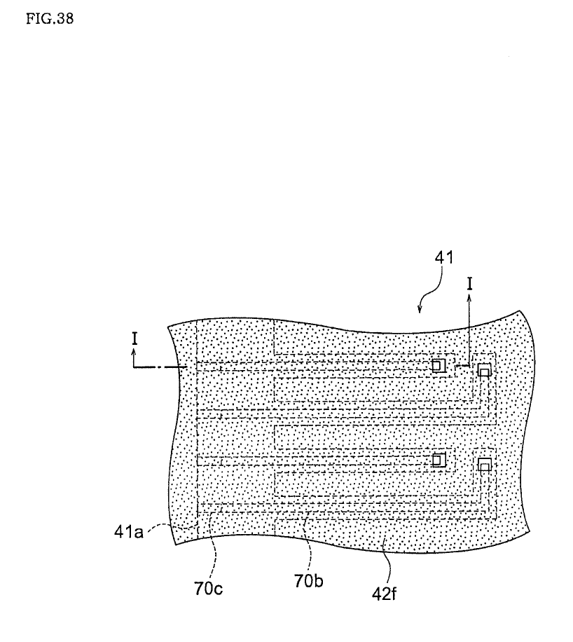

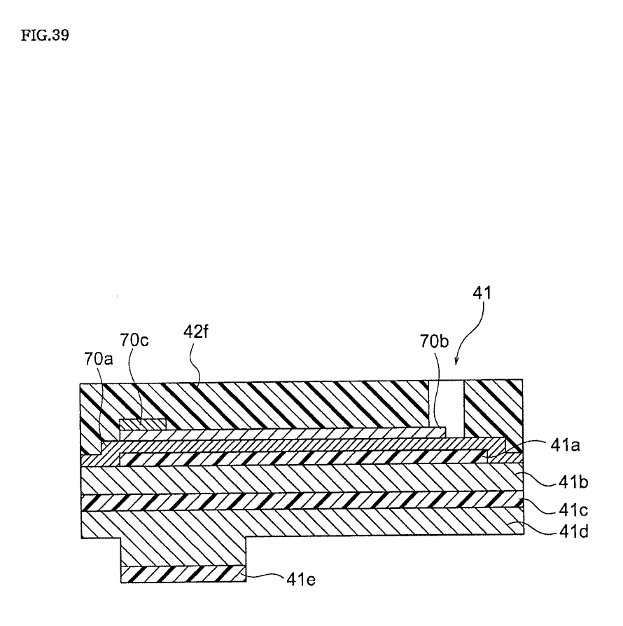

Next, at a 17th step shown in FIG. 38 and FIG. 39, a sixth resist layer 42f is formed on the entire SOI wafer 41 except for the front end portions of the first conductive layers 70b in a similar manner as the above-described fourth step.

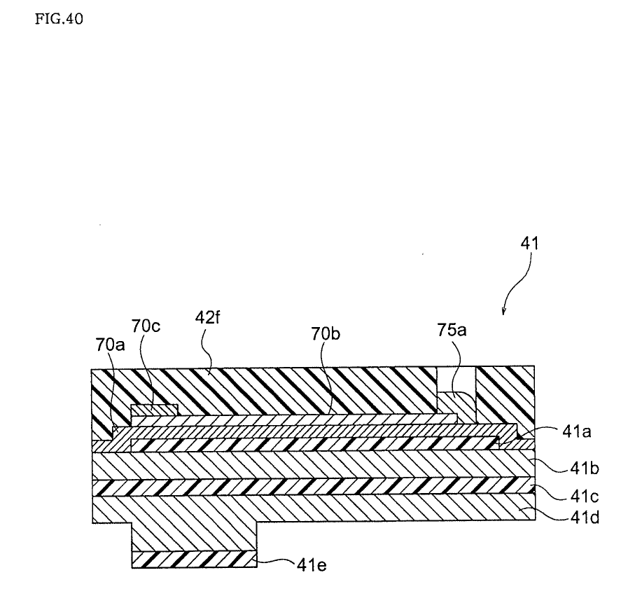

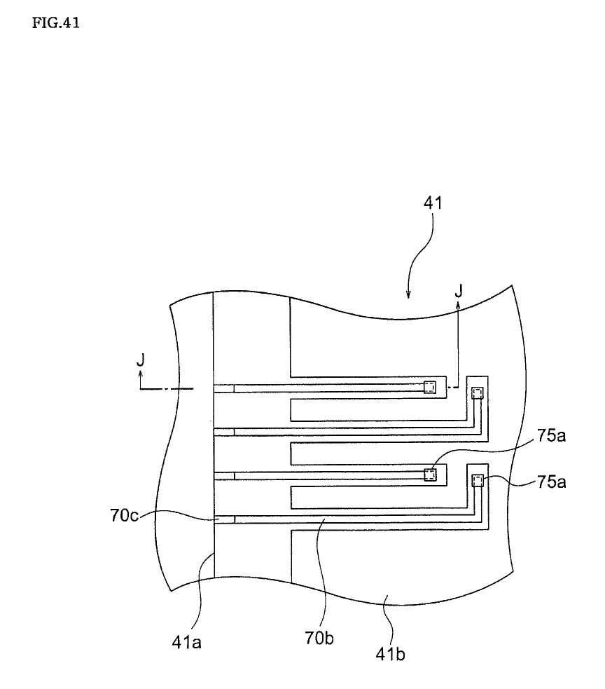

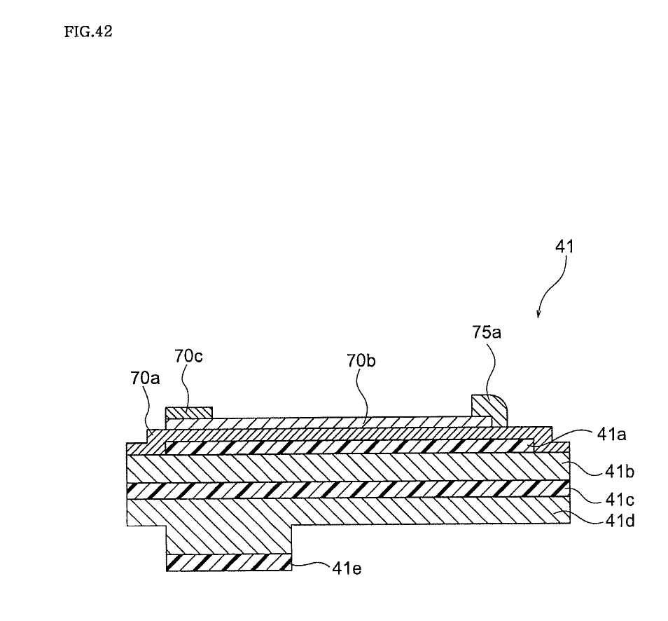

Then, at an 18th step shown in FIG. 40, first contact layers 75a are formed by a plating process on the areas not covered with the sixth resist layer 42f. Each Ni plating layer 75a is formed at a step portion consisting of seed layer 70a and the first conductive layer 70b, and is thus formed into a curved face shape as shown in FIG. 40. Next, at a 19th step shown in FIG. 41 and FIG. 42, the sixth resist layer 42f is removed in a similar manner as the above-described fourth step.

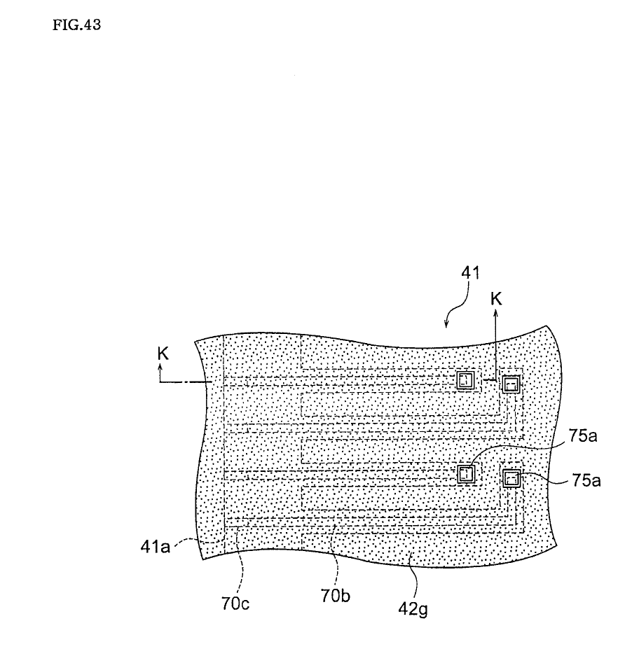

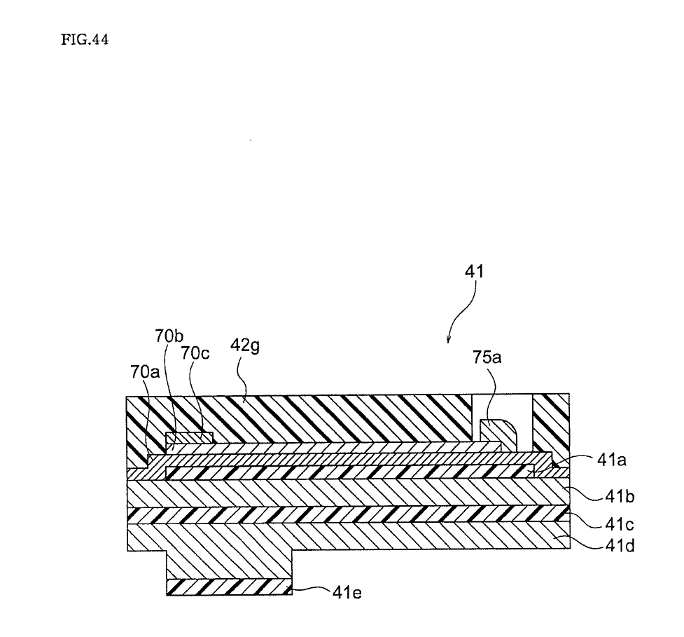

Subsequently, at a 20th step shown in FIG. 43 and FIG. 44, a seventh resist layer 42g is formed on the entire surface of the SOI wafer 41 in a status where certain spaces remain around the first contact layers 75a in a similar manner as the above-described second step.

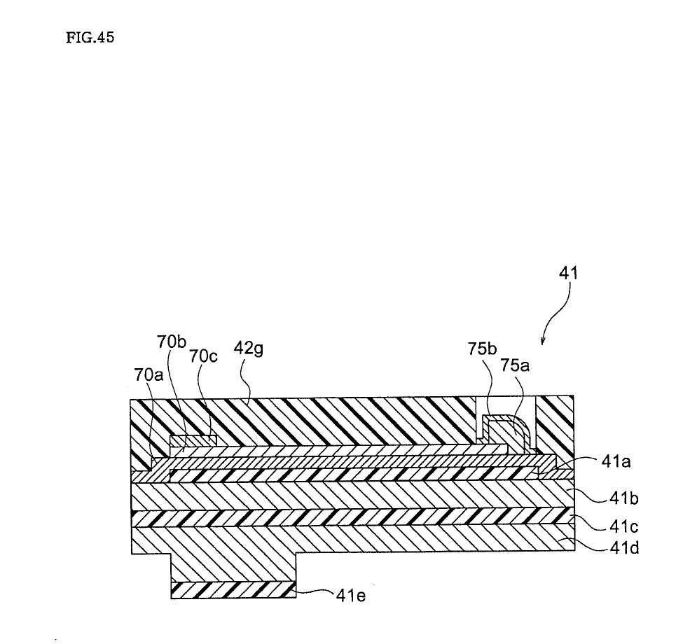

Next, at a 21st step shown in FIG. 45, second contact layers 75b is formed by a gold plating process on the areas of the upper surface of the SOI wafer 41 not covered with the seventh resist 42g so as to envelop the first contact layers 75a. Incidentally these second contact layers 75b are formed for protecting the first contact layers 75a from the plating solution used at the subsequent step for forming third contact layers 75c by rhodium plating.

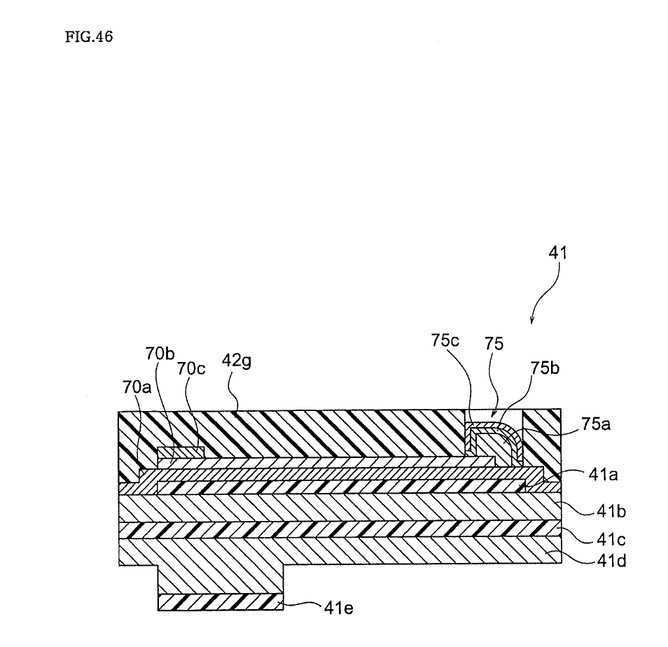

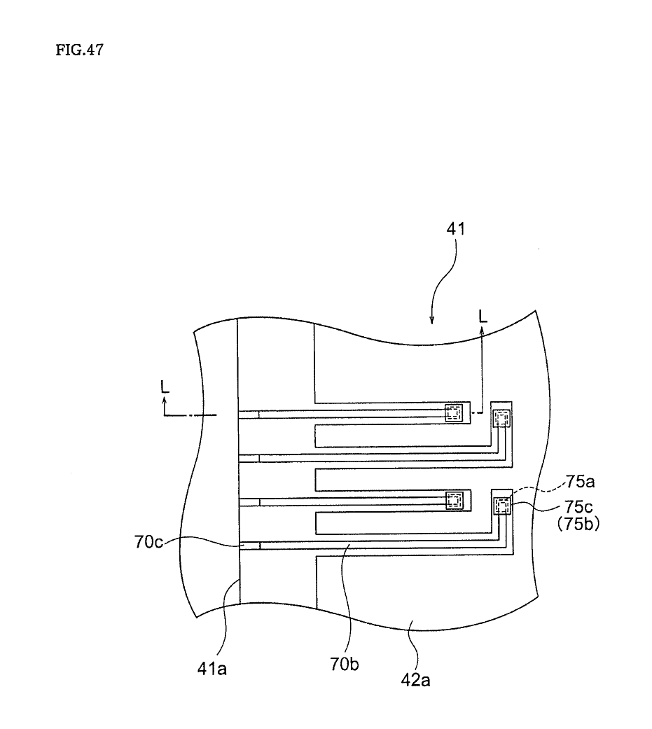

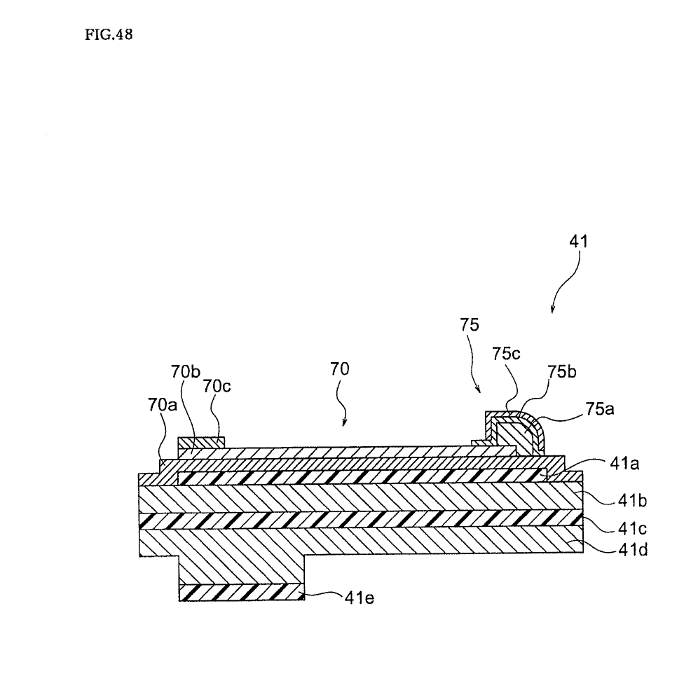

Then, at a 22nd step shown in FIG. 46, in a status where the seventh resist layers 42g remain, the third contact layers 75c are formed by a rhodium plating process on the areas of the upper surface of the SOI wafer 41 not covered with the seventh resist layer 42g so as to envelop the second contact layers 75b. Next, at a 23rd step shown in FIG. 47 and FIG. 48, the seventh resist layer 42g is removed in a similar manner as the above-described fourth step.

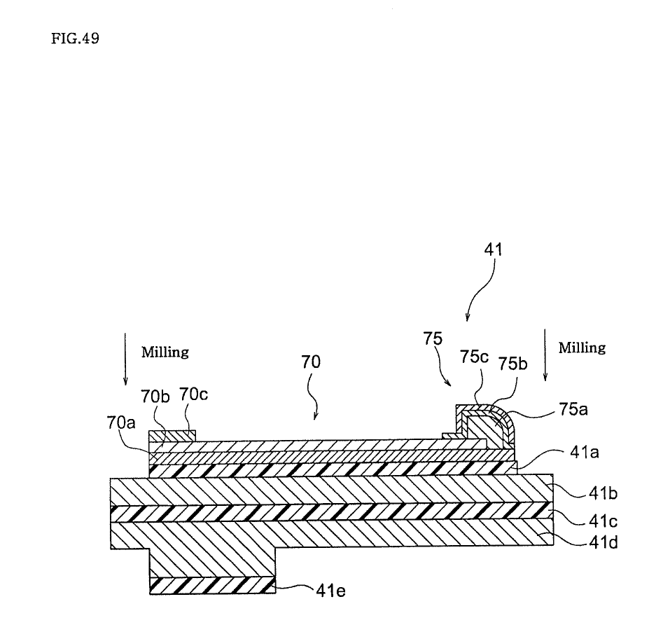

Subsequently, at a 24th step shown in FIG. 49, exteriorly exposed areas of the seed layer 70a are removed by a milling process. This milling process is performed in a vacuum chamber by causing argon ions to collide against the upper surface of the SOI wafer 41. At this time, as the seed layer 70a is thinner than the other layers, the seed layer 70a is removed first during this milling process. Owing to this milling process, only the parts of the seed layer 70a positioned below the first conductive layers 70b and the contact portions 75 remain whereas the other parts are removed.

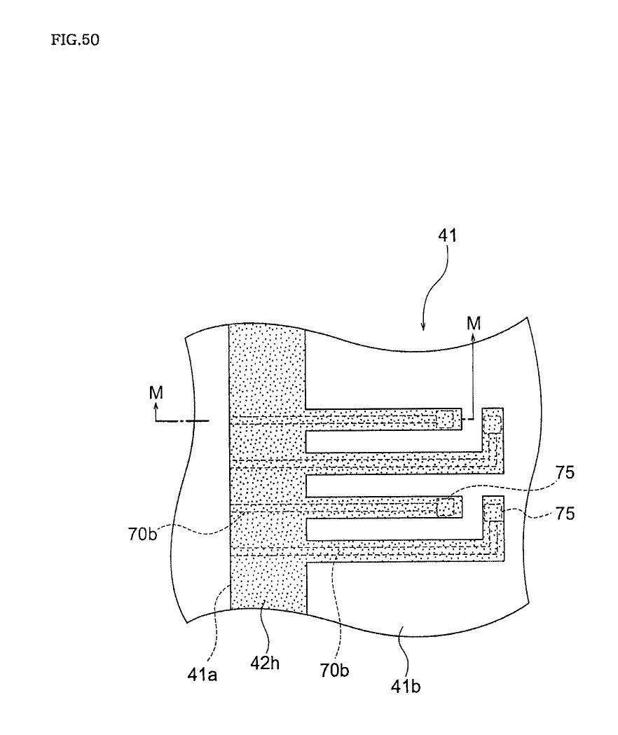

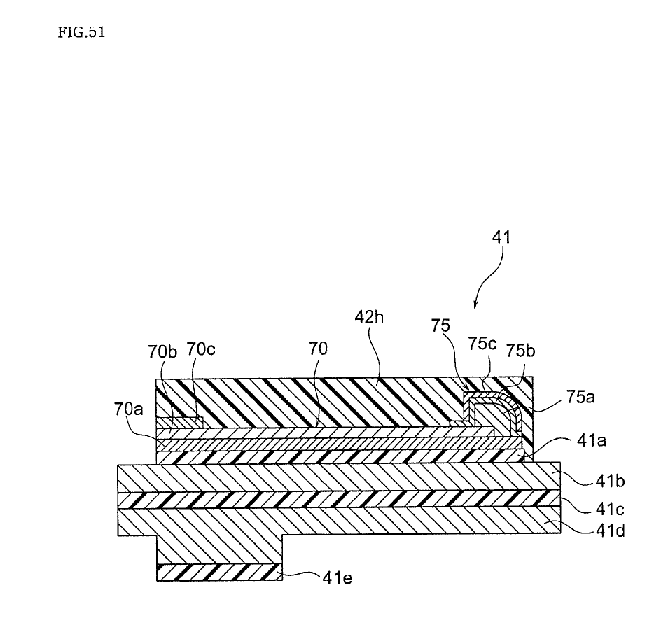

Next, at a 25th step shown in FIG. 50 and FIG. 51, an eighth resist 42h of a shape corresponding to the four beam portions 60 shown in FIG. 5 is formed on the first SiO₂ layer 41a in a similar manner as the above-described second step.

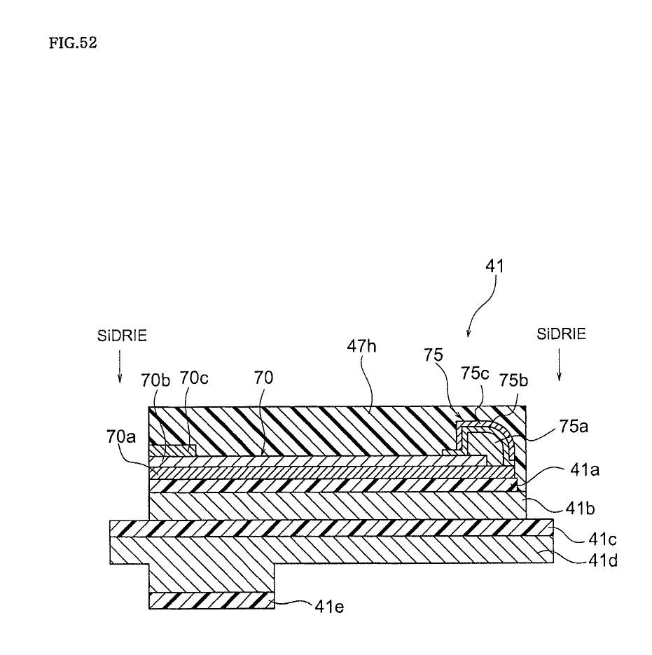

Then, at a 26th step shown in FIG. 52, an etching process to the active layer (Si layer) 41b from above the SOI wafer 41 is performed. Examples of specific method for this etching process may include DRIE method and other methods, for example. Owing to this etching process, the active layer 41b is etched into a shape corresponding to the four beam portions 60 shown in FIG. 5. Note that this etching to the SOI wafer 41 by the DRIE process does not reach the support layer (Si layer) 41d because the BOX layer (SiO₂ layer) 41c acts as an etching stopper.

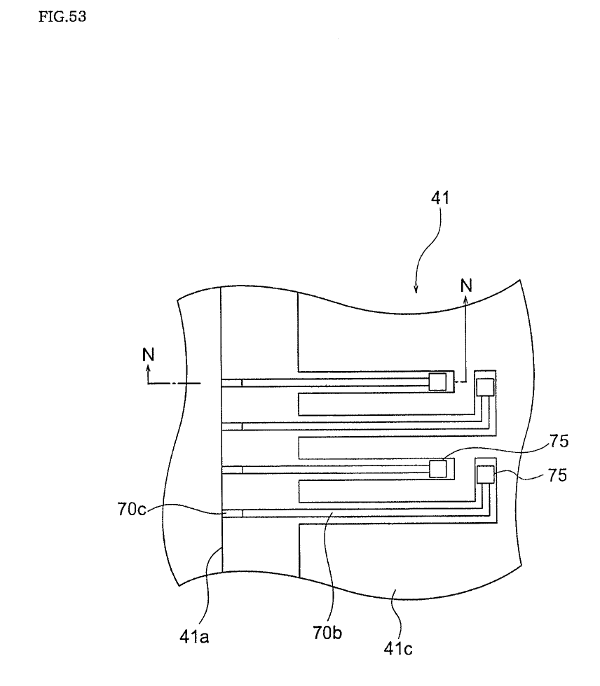

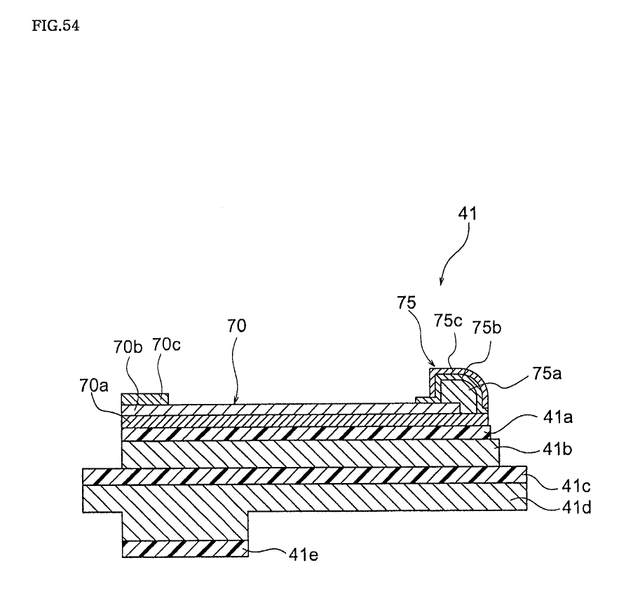

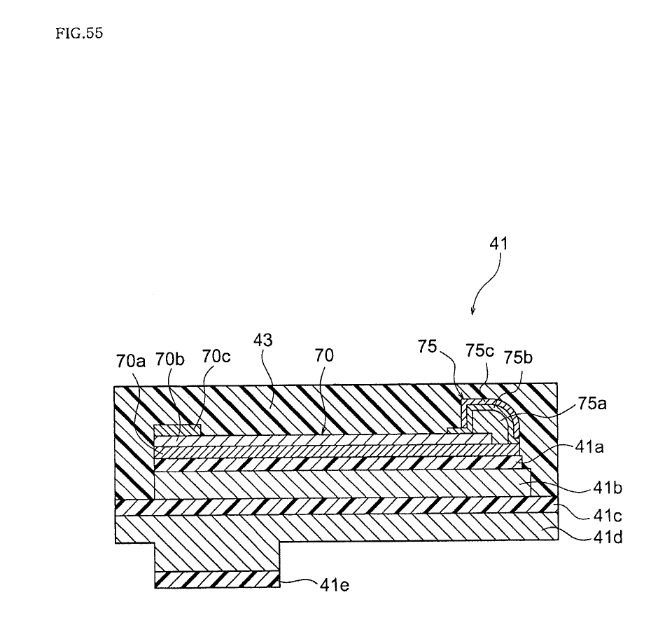

Next, at a 27th step shown in FIG. 53 and FIG. 54, the eighth resist layer 42h is removed in a similar manner as the above-described fourth step. Thereafter, at a 28th step as shown in FIG. 55, a polyimide film 43 is formed on the entire upper surface of the SOI wafer 41. This polyimide film 48 is formed by applying polyimide precursor to the entire upper surface of the SOI wafer 41 using a spin coater, a spray coater or the like and then imidizing it by heating to 20 degree C. or higher or using catalyst. This polyimide film 43 is formed for preventing coolant from leaking by exposure of a stage of the etching apparatus via through holes and for preventing the stage itself from being damaged, at the penetration etching process in the subsequent two steps.

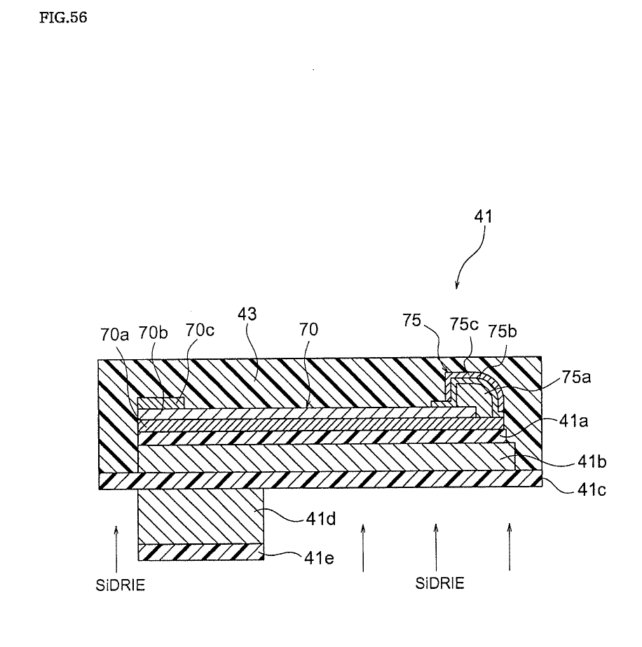

Then, at a 29th step shown in FIG. 56, an etching process to the support layer (Si layer) 41d from below the SOI wafer 41 is performed. Specific examples of this etching process may include DRIE method and other methods, for example. In this etching process, the second SiO₂ layer 41e left after the above-described third step acts as a mask material. Note that this etching from below the SOI wafer 41 by the DRIE process does not reach the active layer (Si layer) 41b because the BOX layer (SiO₂ layer) 41c acts as an etching stopper.

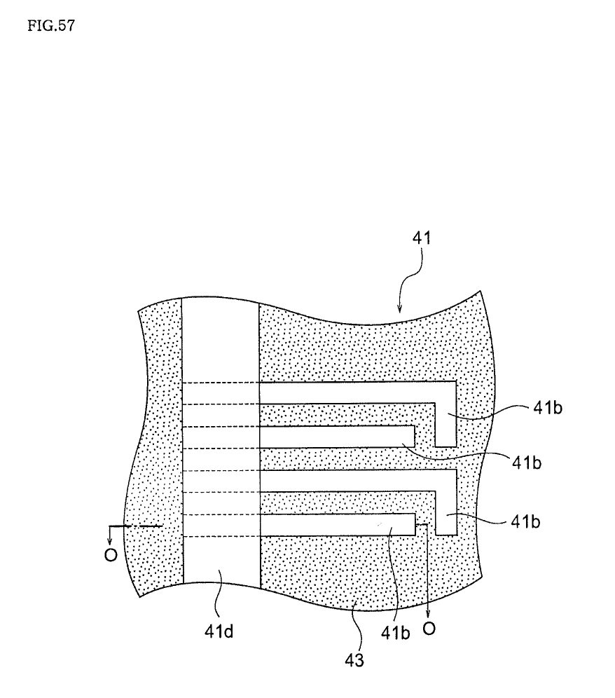

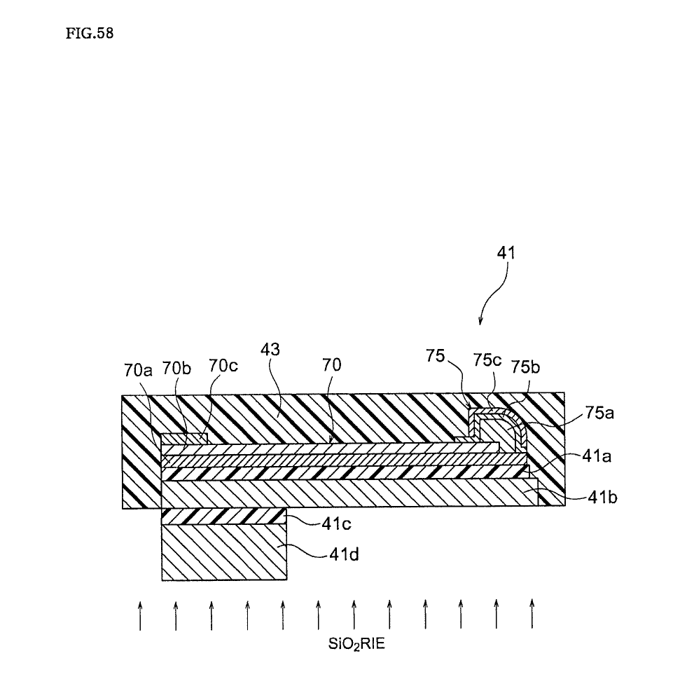

Next, at a 30th step shown in FIG. 57 and FIG. 58, an etching process to the two SiO₂ layers 41c, 41e from below the SOI wafer 41 is performed. Examples of specific method for this etching process may include DRIE method and other methods. As shown in FIG. 57, the four beam portions 60 have shapes completely protruding from the base portion 50 by this etching process.

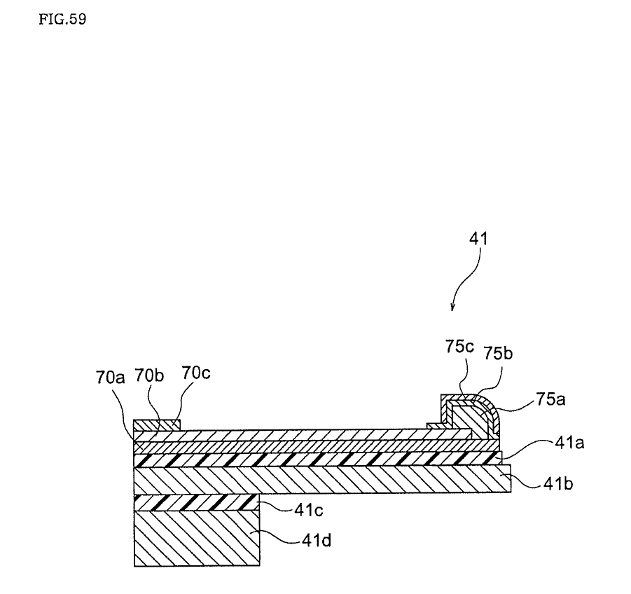

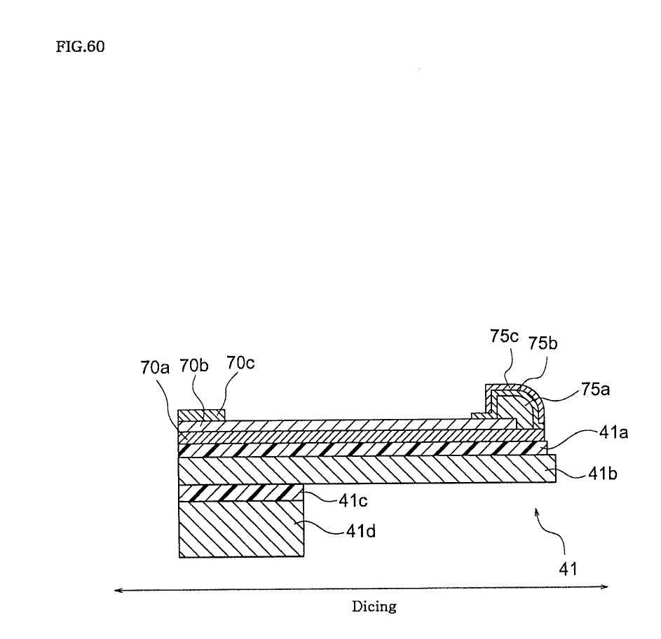

Then, at a 31st step shown in FIG. 59, the polyimide film 43 still unnecessarily remaining is removed by strongly alkaline peeling solution. Thereafter, at a 32nd step shown in FIG. 60, the probes 40 shown in FIG. 5 are accomplished by dicing the SOI wafer 41 along longitudinal directions of the beam portions 60 in units of a predetermined number (four in the present example) of beam portions 60.

The probes 40 produced in such a manner are disposed at predetermined positions on the probe board 31 using a pick-up apparatus not particularly shown and fixed by adhesive, thereby being mounted on the probe board 31.

It is to be noted that the embodiments as explained above are described to facilitate understanding of the present invention and are not described to limit the present invention. Therefore, it is intended that the elements disclosed in the above embodiments include all design changes and equivalents to fall within the technical scope of the present invention.

For example, the shape of probes in the present invention is not particularly limited to the above ones so long as being of a structure in which a plurality of beam portions protrude from a single base portion. Moreover, while the above method of producing the probes involves an application of semiconductor manufacturing technique, the probes in the present invention may be obtained without employing such a semiconductor manufacturing technique.

### DESCRIPTION OF REFERENCE NUMERALS

1 . . . electronic device testing apparatus
   10 . . . test head
   30 . . . probe card
      31 . . . probe board
      40 . . . probe
         50, 50B, 50C . . . base portion
            51 . . . first area
            52 . . . second area
            53 . . . base bent portion
            54 . . . through hole
         60 . . . beam portion
            61 . . . first beam portion
            62, 62B, 62C, 62D . . . second beam portion
            63, 63B, 63C . . . beam bent portion
            64 . . . front end portion
            65 . . . root portion
            66 . . . front end area
      L₀ . . . virtual straight line
         70 . . . conductive pattern
            71, 72 . . . first, second conductive pattern
            73 . . . pattern bent portion
            75 . . . contact portion
   80 . . . tester
   90 . . . prober
   100 . . . semiconductor wafer under test
      110 . . . input and output terminal

1. A probe which contacts terminals of an electronic device under test, the by comprising:
a single base portion;
a plurality of beam portions whose rear end sides are supported by the base portion and whose front end sides protrude from the base portion; and
a plurality of conductive patterns formed on surfaces of the beam portions, wherein
at least a part of the plurality of beam portions has a beam bent portion which is bent in a direction inclined to or substantially perpendicular to a protruding direction of the beam portions.

2. A probe which contacts terminals of an electronic device under test, the probe comprising:
a single base portion;
a plurality of beam portions whose rear end sides are supported by the base portion and whose front end sides protrude from the base portion; and
a plurality of conductive patterns formed on surfaces of the beam portions, wherein
the plurality of beam portions include:
a first beam portion protruding from the base portion; and
a second beam portion protruding from the base portion and having a beam bent portion which is bent in a direction inclined to or substantially perpendicular to a protruding direction of the first beam portion.

3. A probe which contacts terminals of an electronic device under test, the probe comprising:
a single base portion;
a plurality of beam portions whose rear end sides are supported by the base portion and whose front end sides protrude from the base portion; and
a plurality of conductive patterns formed on surfaces of the beam portions, wherein
the plurality of beam portions include:
a first beam portion protruding from the base portion; and
a second beam portion protruding from the base portion such that a projected position of a front end portion of the second beam portion along a protruding direction of the first beam portion is relatively deviated from a root position of the second beam portion.

4. The probe as set forth in claim 2, wherein
a front end area which is positioned at nearer side to a front end than the beam bent portion in the second beam portion is positioned on an extended line from the first beam portion.

5. The probe as set forth in claim 2, wherein
the plurality of conductive patterns include:
a first conductive pattern formed on a surface of the first beam portion; and
a second conductive pattern formed on a surface of the second beam portion, and
a front end portion of the first conductive pattern and a front end portion of the second conductive pattern are positioned on a same virtual straight line along the protruding direction of the first beam portion in planer view.

6. The probe as set forth in claim 1, wherein
the base portion has a base bent portion which is bent.

7. The probe as set forth in claim 6, wherein
the base portion has:
a first area from which the beam portions protrude in a first direction; and
a second area from which the beam portions protrude in a second direction which is different from the first direction, and
the base bent portion interposes between the first area and the second area.

8. The probe as set forth in claim 1, wherein
the base portion has a through hole which is connected with a rear end portion of the conductive pattern and penetrates the base portion.

9. A probe which contacts terminals of an electronic device under test, the probe comprising:
a single base portion;
a plurality of beam portions whose rear end sides are supported by the base portion and whose front end sides protrude from the base portion; and
a plurality of conductive patterns formed on surfaces of the beam portions.

10. A probe card comprising:
the probe as set forth in claim 1; and
a board on which the probe is mounted.

11. An electronic device testing apparatus comprising:
the probe card as set forth in claim 10;
a test head to which the probe card is electrically connected; and
a tester electrically connected to the test head.

12. The probe as set forth in claim 2, wherein
the base portion has a base bent portion which is bent.

13. The probe as set forth in claim 12, wherein
the base portion has:
a first area from which the beam portions protrude in a first direction; and
a second area from which the beam portions protrude in a second direction which is different from the first direction, and
the base bent portion interposes between the first area and the second area.

14. The probe as set forth in claim 2, wherein
the base portion has a through hole which is connected with a rear end portion of the conductive pattern and penetrates the base portion.

15. A probe card comprising:
the probe as set forth in claim 2; and
a board on which the probe is mounted.

16. An electronic device testing apparatus comprising:
the probe card as set forth in claim 15;
a test head to which the probe card is electrically connected; and
a tester electrically connected to the test head.

17. The probe as set forth in claim 3, wherein
the plurality of conductive patterns include:
a first conductive pattern formed on a surface of the first beam portion; and
a second conductive pattern formed on a surface of the second beam portion, and
a front end portion of the first conductive pattern and a front end portion of the second conductive pattern are positioned on a same virtual straight line along the protruding direction of the first beam portion in planer view.

18. The probe as set forth in claim 3, wherein the base portion has a base bent portion which is bent.

19. The probe as set forth in claim 18, wherein
the base portion has:
a first area from which the beam portions protrude in a first direction; and
a second area from which the beam portions protrude in a second direction which is different from the first direction, and
the base bent portion interposes between the first area and the second area.

20. The probe as set forth in claim 3, wherein
the base portion has a through hole which is connected with a rear end portion of the conductive pattern and penetrates the base portion.

21. A probe card comprising:
the probe as set forth in claim 3; and
a board on which the probe is mounted.

22. An electronic device testing apparatus comprising:
the probe card as set forth in claim 21;
a test head to which the probe card is electrically connected; and
a tester electrically connected to the test head.

23. A probe card comprising:
the probe as set forth in claim 9; and
a board on which the probe is mounted.

24. An electronic device testing apparatus comprising:
the probe card as set forth in claim 23;
a test head to which the probe card is electrically connected; and
a tester electrically connected to the test head.
